(19) United States
(12) Patent Application Publication
(10) Pub. No.: US 2020/0357815 A1
(43) Pub. Date: Nov. 12, 2020

(54) A THREE-DIMENSIONAL MEMORY DEVICE HAVING A BACKSIDE CONTACT VIA STRUCTURE WITH A LATERALLY BULGING PORTION AT A LEVEL OF SOURCE CONTACT LAYER

(71) Applicant: SANDISK TECHNOLOGIES LLC, ADDISON, TX (US)

(72) Inventors: Takaaki Iwai, Yokkaichi (JP); Makoto Koto, Yokkaichi (JP); Masanori Terahara, Yokkaichi (JP)

(21) Appl. No.: 16/406,335

(22) Filed: May 8, 2019

(51) Int. Cl. H01L 27/11582; H01L 27/11519; H01L 27/11556; H01L 27/11565; H01L 23/522; H01L 21/768

(52) U.S. Cl. CPC H01L 27/11582; H01L 27/11519; H01L 27/11556; H01L 21/32134; H01L 23/5226; H01L 21/76805; H01L 21/76831; H01L 27/11565

(57) ABSTRACT

A lower source layer, a sacrificial source-level material layer, and an upper source layer are formed over a substrate. The lower source layer includes a recess trench in which a recessed surface of the lower source layer is vertically recessed relative to a topmost surface of the lower source layer. An alternating stack of insulating layers and spacer material layers is subsequently formed. Memory stack structures are formed through the alternating stack. A backside trench is formed through the alternating stack such that a bottom surface of the backside trench is formed within an area of the recess trench in a thickened portion of the sacrificial source-level material layer. The sacrificial source-level material layer is replaced with a source contact layer.

### FIELD

The present disclosure relates generally to the field of semiconductor devices, and particular to a three-dimensional memory device including backside contact structures and methods of manufacturing the same.

### BACKGROUND

A three-dimensional memory device including three-dimensional vertical NAND strings having one bit per cell are disclosed in an article by T. Endoh et al., titled “Novel Ultra High Density Memory With A Stacked-Surrounding Gate Transistor (S-SGT) Structured Cell”, IEDM Proc. (2001) 33-36.

### SUMMARY

According to an embodiment of the present disclosure, a three-dimensional memory device is provided, which comprises: source-level material layers located over a substrate, wherein the source-level material layers comprise, from bottom to top, a lower source layer, a source contact layer, and an upper source layer, wherein the lower source layer comprises a first horizontal surface located within a first horizontal plane and contacting a bottom surface of the source contact layer and a second horizontal surface located within a second horizontal plane located below the first horizontal plane; an alternating stack of insulating layers and electrically conductive layers located over the source-level material layers; memory stack structures vertically extending through the alternating stack and comprising a respective memory film and a respective vertical semiconductor channel having a sidewall that contacts the source contact layer; and a backside contact via structure extending through each layer within the alternating stack, the upper source layer, the source contact layer, and an opening through the second horizontal surface and contacting the lower source layer.

According to another embodiment of the present disclosure, a method of forming a three-dimensional memory device is provided, which comprises the steps of: forming in-process source-level material layers over a substrate, wherein the in-process source-level material layers comprise a lower source layer, a sacrificial source-level material layer, and an upper source layer, wherein the lower source layer comprises a recess trench in which a recessed surface of the lower source layer is vertically recessed relative to a topmost surface of the lower source layer, and the sacrificial source-level material layer comprises a sacrificial recess trench fill portion that that protrudes downward and fills the recess region; forming an alternating stack of insulating layers and spacer material layers over the in-process source-level material layers; forming memory stack structures vertically extending through the alternating stack, wherein each of the memory stack structures comprises a respective memory film and a respective vertical semiconductor channel; forming a backside trench through the alternating stack such that a bottom surface of the backside trench is formed within an area of the recess trench between a top surface of the sacrificial source-level material layer and the recessed surface of the lower source layer; and replacing the sacrificial source-level material layer with a source contact layer.

### BRIEF DESCRIPTION OF THE DRAWINGS

FIG. 1A is a vertical cross-sectional view of an exemplary structure after formation of a dielectric isolation layer, a lower source layer, a first dielectric pad layer, a second dielectric pad layer, and recess trenches according to an embodiment of the present disclosure.

FIG. 1B is a top-down view of the exemplary structure of FIG. 1A. The hinged vertical plane A-A′ is the plane of the vertical cross-sectional view of FIG. 1A.

FIG. 1C is a magnified vertical cross-sectional view of a region of the exemplary structure along the vertical plane C-C′ of FIG. 1B.

FIG. 2 is a magnified vertical cross-sectional view of a region of the exemplary structure after formation of a lower etch stop dielectric liner according to an embodiment of the present disclosure.

FIG. 3 is a magnified vertical cross-sectional view of a region of the exemplary structure after formation of a sacrificial source-level material layer according to an embodiment of the present disclosure.

FIG. 4A is a vertical cross-sectional view of an exemplary structure after formation of an upper etch stop dielectric layer and an upper source layer according to an embodiment of the present disclosure.

FIG. 4B is a top-down view of the exemplary structure of FIG. 4A. The hinged vertical plane A-A′ is the plane of the vertical cross-sectional view of FIG. 4A.

FIG. 4C is a magnified vertical cross-sectional view of a region of the exemplary structure along the vertical plane C-C′ of FIG. 4B.

FIG. 5 is a vertical cross-sectional view of the exemplary structure after formation of a first-tier alternating stack of first insulting layers and first spacer material layers according to an embodiment of the present disclosure.

FIG. 6 is a vertical cross-sectional view of the exemplary structure after patterning a first-tier staircase region, a first retro-stepped dielectric material portion, and an inter-tier dielectric layer according to an embodiment of the present disclosure.

FIG. 7A is a vertical cross-sectional view of the exemplary structure after formation of first-tier memory openings and first-tier support openings according to an embodiment of the present disclosure.

FIG. 7B is a horizontal cross-sectional view of the exemplary structure of FIG. 7A. The hinged vertical plane A-A′ corresponds to the plane of the vertical cross-sectional view of FIG. 7A.

FIG. 8 is a vertical cross-sectional view of the exemplary structure after formation of various sacrificial fill structures according to an embodiment of the present disclosure.

FIG. 9 is a vertical cross-sectional view of the exemplary structure after formation of a second-tier alternating stack of second insulating layers and second spacer material layers, second stepped surfaces, and a second retro-stepped dielectric material portion according to an embodiment of the present disclosure.

FIG. 10A is a vertical cross-sectional view of the exemplary structure after formation of second-tier memory openings and second-tier support openings according to an embodiment of the present disclosure.

FIG. 10B is a horizontal cross-sectional view of the exemplary structure along the horizontal plane B-B′ of FIG. 10A. The hinged vertical plane A-A′ corresponds to the plane of the vertical cross-sectional view of FIG. 10A.

FIG. 11 is a vertical cross-sectional view of the exemplary structure after formation of inter-tier memory openings and inter-tier support openings according to an embodiment of the present disclosure.

FIGS. 12A-12D illustrate sequential vertical cross-sectional views of a memory opening during formation of a memory opening fill structure according to an embodiment of the present disclosure.

FIG. 13 is a vertical cross-sectional view of the exemplary structure after formation of memory opening fill structures and support pillar structures according to an embodiment of the present disclosure.

FIG. 14A is a vertical cross-sectional view of the exemplary structure after formation of pillar cavities according to an embodiment of the present disclosure.

FIG. 14B is a horizontal cross-sectional view of the exemplary structure along the horizontal plane B-B′ of FIG. 14A. The hinged vertical plane A-A′ corresponds to the plane of the vertical cross-sectional view of FIG. 14A.

FIG. 15 is a vertical cross-sectional view of the exemplary structure after formation of dielectric pillar structures according to an embodiment of the present disclosure.

FIG. 16A is a vertical cross-sectional view of the exemplary structure after formation of a first contact level dielectric layer and backside trenches according to an embodiment of the present disclosure.

FIG. 16B is a horizontal cross-sectional view of the exemplary structure along the horizontal plane B-B′ of FIG. 16A. The hinged vertical plane A-A′ corresponds to the plane of the vertical cross-sectional view of FIG. 16A.

FIG. 17 is a vertical cross-sectional view of the exemplary structure after formation of backside trench spacers according to an embodiment of the present disclosure.

FIGS. 18A-18F illustrate sequential vertical cross-sectional views of memory opening fill structures and a backside trench during formation of source-level material layers according to an embodiment of the present disclosure.

FIG. 19 is a vertical cross-sectional view of the exemplary structure after formation of source-level material layers according to an embodiment of the present disclosure.

FIG. 20 is a vertical cross-sectional view of the exemplary structure after formation of backside recesses according to an embodiment of the present disclosure.

FIG. 21 is a vertical cross-sectional view of the exemplary structure after formation of electrically conductive layers according to an embodiment of the present disclosure.

FIGS. 22A-22D illustrate sequential vertical cross-sectional views of a region of the exemplary structure including a backside trench during formation of a backside contact via structure according to an embodiment of the present disclosure.

FIG. 23A is a vertical cross-sectional view of the exemplary structure after formation of backside trench fill structures in the backside trenches according to an embodiment of the present disclosure.

FIG. 23B is a horizontal cross-sectional view of the exemplary structure along the horizontal plane B-B′ of FIG. 23A. The hinged vertical plane A-A′ corresponds to the plane of the vertical cross-sectional view of FIG. 23A.

FIG. 23C is a vertical cross-sectional view of the exemplary structure along the vertical plane C-C′ of FIG. 23B.

FIG. 24A is a vertical cross-sectional view of the exemplary structure after formation of a second contact level dielectric layer and various contact via structures according to an embodiment of the present disclosure.

FIG. 24B is a horizontal cross-sectional view of the exemplary structure along the vertical plane B-B′ of FIG. 24A. The hinged vertical plane A-A′ corresponds to the plane of the vertical cross-sectional view of FIG. 24A.

FIG. 25 is a vertical cross-sectional view of the exemplary structure after formation of upper metal line structures according to an embodiment of the present disclosure.

### DETAILED DESCRIPTION

As discussed above, the present disclosure is directed to a three-dimensional memory device including backside contact structures and methods of manufacturing the same, the various embodiments of which are described herein in detail. Various embodiments are disclosed that provide backside contact structures for enabling robust source contact. The embodiments of the present disclosure may be used to form various semiconductor devices such as three-dimensional monolithic memory array devices comprising a plurality of NAND memory strings.

The drawings are not drawn to scale. Multiple instances of an element may be duplicated where a single instance of the element is illustrated, unless absence of duplication of elements is expressly described or clearly indicated otherwise. Ordinals such as “first,” “second,” and “third” are used merely to identify similar elements, and different ordinals may be used across the specification and the claims of the instant disclosure. The same reference numerals refer to the same element or similar element. Unless otherwise indicated, elements having the same reference numerals are presumed to have the same composition and the same function. Unless otherwise indicated, a “contact” between elements refers to a direct contact between elements that provides an edge or a surface shared by the elements. As used herein, a first element located “on” a second element may be located on the exterior side of a surface of the second element or on the interior side of the second element. As used herein, a first element is located “directly on” a second element if there exist a physical contact between a surface of the first element and a surface of the second element. As used herein, a first element is “electrically connected to” a second element if there exists a conductive path consisting of at least one conductive material between the first element and the second element. As used herein, a “prototype” structure or an “in-process” structure refers to a transient structure that is subsequently modified in the shape or composition of at least one component therein.

As used herein, a “layer” refers to a material portion including a region having a thickness. A layer may extend over the entirety of an underlying or overlying structure, or may have an extent less than the extent of an underlying or overlying structure. Further, a layer may be a region of a homogeneous or inhomogeneous continuous structure that has a thickness less than the thickness of the continuous structure. For example, a layer may be located between any pair of horizontal planes between, or at, a top surface and a bottom surface of the continuous structure. A layer may extend horizontally, vertically, and/or along a tapered surface. A substrate may be a layer, may include one or more layers therein, or may have one or more layer thereupon, thereabove, and/or therebelow.

As used herein, a first surface and a second surface are “vertically coincident” with each other if the second surface overlies or underlies the first surface and there exists a vertical plane or a substantially vertical plane that includes the first surface and the second surface. A substantially vertical plane is a plane that extends straight along a direction that deviates from a vertical direction by an angle less than 5 degrees. A vertical plane or a substantially vertical plane is straight along a vertical direction or a substantially vertical direction, and may, or may not, include a curvature along a direction that is perpendicular to the vertical direction or the substantially vertical direction.

As used herein, a “memory level” or a “memory array level” refers to the level corresponding to a general region between a first horizontal plane (i.e., a plane parallel to the top surface of the substrate) including topmost surfaces of an array of memory elements and a second horizontal plane including bottommost surfaces of the array of memory elements. As used herein, a “through-stack” element refers to an element that vertically extends through a memory level.

As used herein, a “semiconducting material” refers to a material having electrical conductivity in the range from 1.0×10⁻⁵ S/m to 1.0×107 S/m. As used herein, a “semiconductor material” refers to a material having electrical conductivity in the range from 1.0×10⁻⁵ S/m to 1.0 S/m in the absence of electrical dopants therein, and is capable of producing a doped material having electrical conductivity in a range from 1.0 S/m to 1.0×10⁷ S/m upon suitable doping with an electrical dopant. As used herein, an “electrical dopant” refers to a p-type dopant that adds a hole to a valence band within a band structure, or an n-type dopant that adds an electron to a conduction band within a band structure. As used herein, a “conductive material” refers to a material having electrical conductivity greater than 1.0×107 S/m. As used herein, an “insulator material” or a “dielectric material” refers to a material having electrical conductivity less than 1.0×10⁻⁵ S/m. As used herein, a “heavily doped semiconductor material” refers to a semiconductor material that is doped with electrical dopant at a sufficiently high atomic concentration to become a conductive material either as formed as a crystalline material or if converted into a crystalline material through an anneal process (for example, from an initial amorphous state), i.e., to provide electrical conductivity greater than 1.0×107 S/m. A “doped semiconductor material” may be a heavily doped semiconductor material, or may be a semiconductor material that includes electrical dopants (i.e., p-type dopants and/or n-type dopants) at a concentration that provides electrical conductivity in the range from 1.0×10⁻⁵ S/m to 1.0×10⁷ S/m. An “intrinsic semiconductor material” refers to a semiconductor material that is not doped with electrical dopants. Thus, a semiconductor material may be semiconducting or conductive, and may be an intrinsic semiconductor material or a doped semiconductor material. A doped semiconductor material may be semiconducting or conductive depending on the atomic concentration of electrical dopants therein. As used herein, a “metallic material” refers to a conductive material including at least one metallic element therein. All measurements for electrical conductivities are made at the standard condition.

A monolithic three-dimensional memory array is one in which multiple memory levels are formed above a single substrate, such as a semiconductor wafer, with no intervening substrates. The term “monolithic” means that layers of each level of the array are directly deposited on the layers of each underlying level of the array. In contrast, two dimensional arrays may be formed separately and then packaged together to form a non-monolithic memory device. For example, non-monolithic stacked memories have been constructed by forming memory levels on separate substrates and vertically stacking the memory levels, as described in U.S. Pat. No. 5,915,167 titled “Three-dimensional Structure Memory.” The substrates may be thinned or removed from the memory levels before bonding, but as the memory levels are initially formed over separate substrates, such memories are not true monolithic three-dimensional memory arrays. The substrate may include integrated circuits fabricated thereon, such as driver circuits for a memory device

The various three-dimensional memory devices of the present disclosure include a monolithic three-dimensional NAND string memory device, and may be fabricated using the various embodiments described herein. The monolithic three-dimensional NAND string is located in a monolithic, three-dimensional array of NAND strings located over the substrate. At least one memory cell in the first device level of the three-dimensional array of NAND strings is located over another memory cell in the second device level of the three-dimensional array of NAND strings.

Generally, a semiconductor package (or a “package”) refers to a unit semiconductor device that may be attached to a circuit board through a set of pins or solder balls. A semiconductor package may include a semiconductor chip (or a “chip”) or a plurality of semiconductor chips that are bonded throughout, for example, by flip-chip bonding or another chip-to-chip bonding. A package or a chip may include a single semiconductor die (or a “die”) or a plurality of semiconductor dies. A die is the smallest unit that may independently execute external commands or report status. Typically, a package or a chip with multiple dies is capable of simultaneously executing as many external commands as the total number of dies therein. Each die includes one or more planes. Identical concurrent operations may be executed in each plane within a same die, although there may be some restrictions. In case a die is a memory die, i.e., a die including memory elements, concurrent read operations, concurrent write operations, or concurrent erase operations may be performed in each plane within a same memory die. In a memory die, each plane contains a number of memory blocks (or “blocks”), which are the smallest unit that may be erased by in a single erase operation. Each memory block contains a number of pages, which are the smallest units that may be selected for programming. A page is also the smallest unit that may be selected to a read operation.

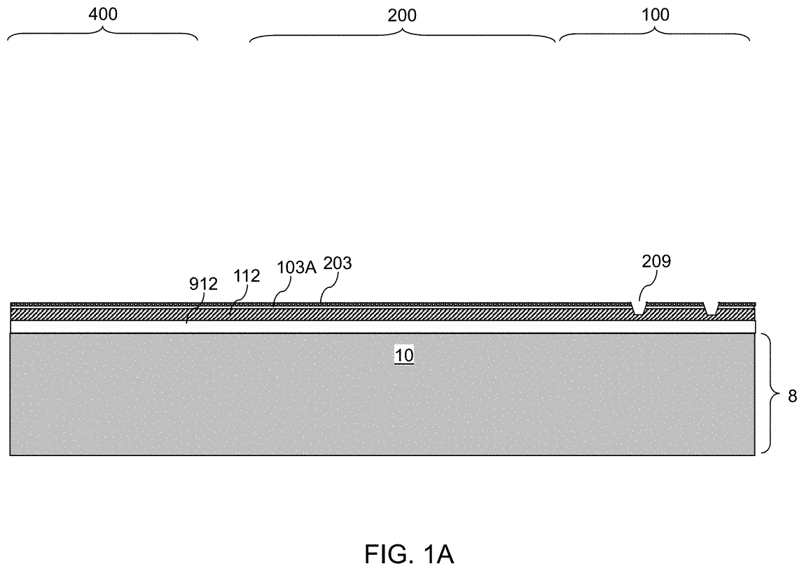

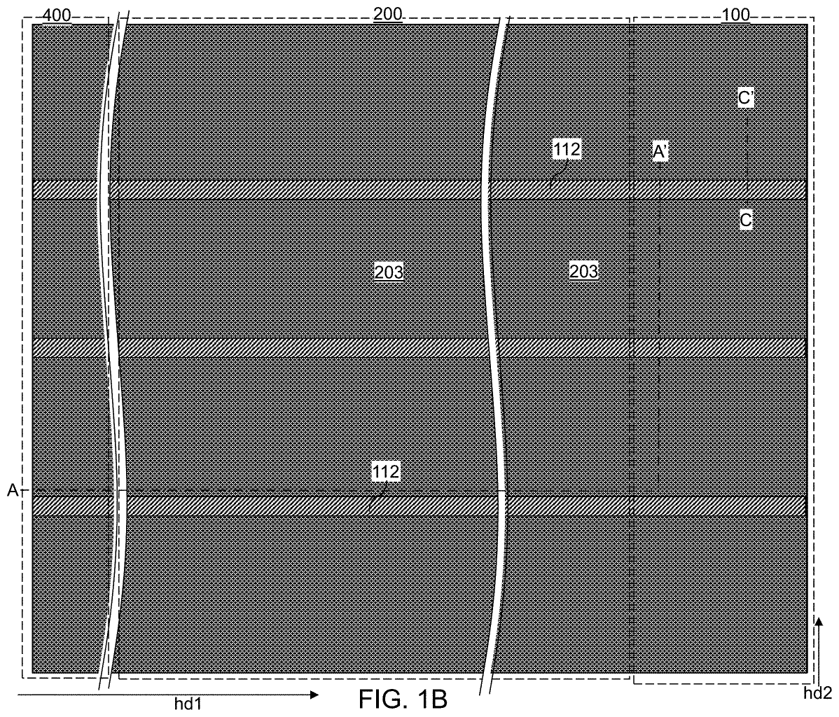

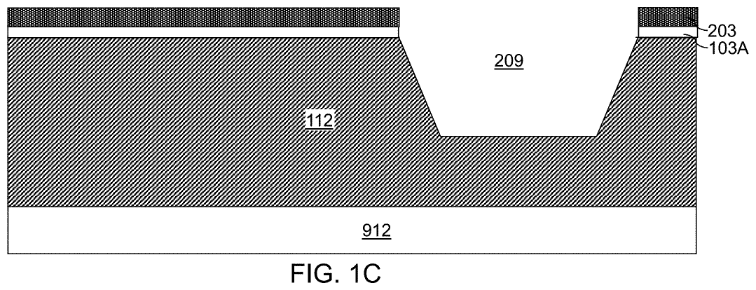

Referring to FIGS. 1A-1C, an exemplary structure according to an embodiment of the present disclosure is illustrated. The exemplary structure includes a substrate 8 that includes a substrate material layer 10. The substrate 8 may be a semiconductor substrate, an insulating substrate, or a conductive substrate. In one embodiment, the substrate 8 may include a commercially available silicon substrate. In this case, the substrate material layer 10 may include a single crystalline silicon layer. Optionally, at least one semiconductor device such as field effect transistors may be formed on the substrate 8.

A dielectric isolation layer 912 may be optionally formed on the top surface of the substrate material layer 10. The dielectric isolation layer 912 may include a dielectric material such as silicon oxide. The thickness of the dielectric isolation layer 912 may be in a range from 10 nm to 1,000 nm, although lesser and greater thicknesses may also be used.

A lower source layer 112 may be deposited on a top surface of the dielectric isolation layer 912. The lower source layer 112 may have a doping of the same conductivity type as a source contact layer to be subsequently formed, and may have a doping of an opposite conductivity type of vertical semiconductor channels to be subsequently formed. For example, if the vertical semiconductor channels to be subsequently formed have a doping of a first conductivity type, the lower source layer 112 may have a doping of a second conductivity type that is the opposite of the first conductivity type. If the first conductivity type is p-type, the second conductivity type is n-type, and vice versa.

The thickness of the lower source layer 112 may be in a range from 50 nm to 500 nm, such as from 75 nm to 200 nm, although lesser and greater thicknesses may also be used. In one embodiment, the lower source layer 112 may include polysilicon having a doping of the second conductivity type. Atomic concentration of dopants of the second conductivity type in the lower source layer 112 may be in a range from 1.0×10¹⁹/cm³ to 2.0×10²¹/cm³, although lesser and greater atomic concentrations may also be used.

A first dielectric pad layer 103A may be formed on the top surface of the lower source layer 112. The first dielectric pad layer 103A includes a dielectric material that may function as an etch stop material during subsequently removal of a sacrificial material. For example, the first dielectric pad layer 103A may include silicon oxide. The first dielectric pad layer 103A may have a thickness in a range from 2 nm to 10 nm, although lesser and greater thicknesses may also be used.

A second dielectric pad layer 203 may be optionally formed on the top surface of the first dielectric pad layer 103A. The second dielectric pad layer 203 includes a dielectric material that may function as an etch mask for etching the material of the lower source layer 112, and may be removed selective to the first dielectric pad layer 103A. For example, if the first dielectric pad layer 103A includes silicon oxide, the second dielectric pad layer 203 may include silicon nitride. The second dielectric pad layer 203 may have a thickness in a range from 10 nm to 150 nm, although lesser and greater thicknesses may also be used.

The exemplary structure includes a memory array region 100 in which an array of memory devices may be subsequently formed, a staircase region 200 in which stepped surfaces of an alternating stack of insulating layers and electrically conductive layers may be subsequently formed, and a peripheral region 400 from which layers within the alternating stack of insulating layers and electrically conductive layers may be subsequently removed. A photoresist layer (not shown) may be applied over the second dielectric pad layer 203, and may be lithographically patterned to form elongated openings that extend along a first horizontal direction hd1. The first horizontal direction hd1 may be a horizontal direction that is perpendicular to the boundary between the memory array region 100 and the staircase region 200. A second horizontal direction hd2 that is perpendicular to the first horizontal direction hd1 may be parallel to the boundary between the memory array region 100 and the staircase region 200. Line trenches having a uniform width may be provided within each neighboring pair of patterned portions of the photoresist layer. The areas of the line trenches may be selected to be greater than the areas of backside trenches to be subsequently formed, and may be located between clusters of memory openings to be subsequently formed.

An anisotropic etch process may be performed to transfer the pattern in the photoresist layer through the second dielectric pad layer 203, the first dielectric pad layer 103A, and an upper portion of the lower source layer 112. Recess trenches 209 may be formed in the upper portion of the lower source layer 112. The recess trenches 209 may laterally extend along the first horizontal direction with a uniform width (as measured in the horizontal plane including the top surface of the lower source layer 112). The width of each recess trench 209 at a top portion thereof may be in a range from 100 nm to 2,000 nm, such as from 200 nm to 1,000 nm. The depth of each recess trench 209, as measured between the horizontal plane including the top surface of the lower source layer 112 and the bottom surface of each recess trench 209, may be in a range from 20% to 90% of the initial thickness of the lower source layer. For example, the depth of each recess trench 209 may be in a range from 10 nm to 450 nm, such as from 50 nm to 200 nm, although lesser and greater depths may also be used. The photoresist layer may be subsequently removed, for example, by ashing.

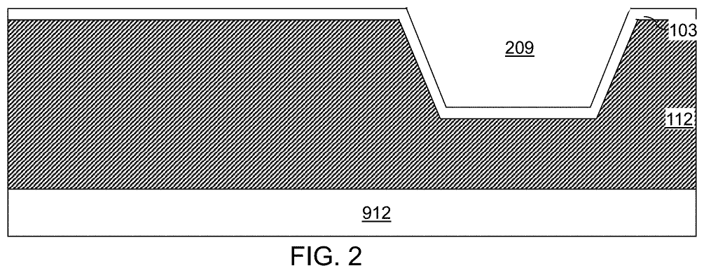

Referring to FIG. 2, a thermal conversion process or a plasma conversion process may be performed to convert physically exposed surface portions of the lower source layer 112 into dielectric liner portions. For example, a thermal oxidation process or a plasma oxidation process may be performed to convert physically exposed surface portions of the lower source layer 112 into silicon oxide liner portions. The converted dielectric liner portions may have the same composition as, or a similar composition as, the first dielectric pad layer 103A. A continuous layer incorporating the first dielectric pad layer 103A and the dielectric liner portions may be formed, which is herein referred to as a lower etch stop dielectric liner 103. The lower etch stop dielectric liner 103 may be subsequently used as an etch stop layer during subsequently removal of a sacrificial source-level material layer. In one embodiment, the lower etch stop dielectric liner 103 may comprise a silicon oxide layer. The lower etch stop dielectric liner 103 may have a thickness in a range from 2 nm to 10 nm, although lesser and greater thicknesses may also be used. Once the physically exposed surface portions of the lower source layer 112 into silicon oxide liner portions, the second dielectric pad layer 203 may be removed, for example, by a wet etch process. Such wet etch processes may use, for example, hot phosphoric acid.

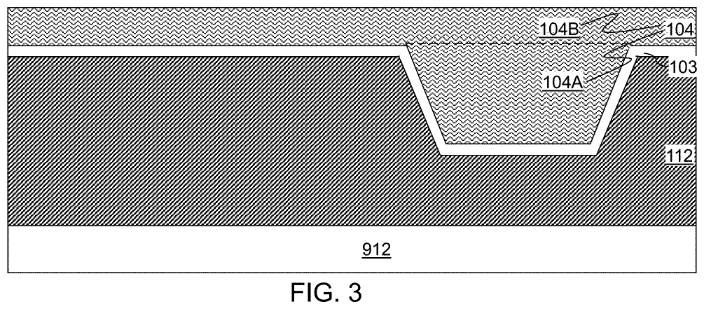

Referring to FIG. 3, a sacrificial fill material may be deposited in the recess trenches 209 and over the topmost surface of the lower etch stop dielectric liner 103. The sacrificial fill material may include a material that is removed selective to the lower etch stop dielectric liner 103. For example, the sacrificial fill material may include undoped amorphous silicon, amorphous carbon, organosilicate glass, or a polymer material. In one embodiment, the sacrificial fill material includes undoped amorphous silicon. The sacrificial fill material may be subsequently planarized to provide a planar top surface. A sacrificial source-level material layer 104 may be formed by a remaining portion of the sacrificial fill material. The sacrificial source-level material layer 104 may include sacrificial recess trench fill portions 104A that fills the recess trenches 209 and a planar sacrificial material portion 104B that overlies the topmost surface of the lower etch stop dielectric liner 103. The planar sacrificial material portion 104B is a planar portion of the sacrificial source-level material layer 104. The planar sacrificial material portion 104B may have a uniform thickness throughout, which may be in a range from 15 nm to 100 nm, such as from 20 nm to 50 nm, although lesser and greater thicknesses may also be used.

In one embodiment, materials of the sacrificial recess trench fill portions 104A and the planar sacrificial material portion 104B may be deposited in a same deposition process, and a planarization process such as chemical mechanical planarization process may be performed to provide a planar top surface to the sacrificial source-level material layer 104. Alternatively, the sacrificial recess trench fill portions 104A may be formed by deposition and planarization of a first sacrificial material, and the planar sacrificial material portion 104B may be formed by deposition and planarization of a second sacrificial material. In one embodiment, the sacrificial source-level material layer 104 may consist essentially of a single sacrificial fill material such as undoped amorphous silicon.

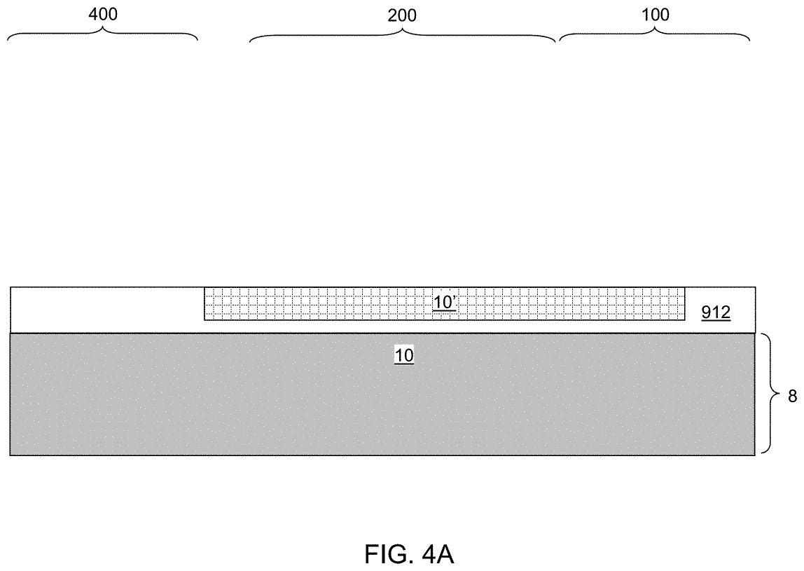

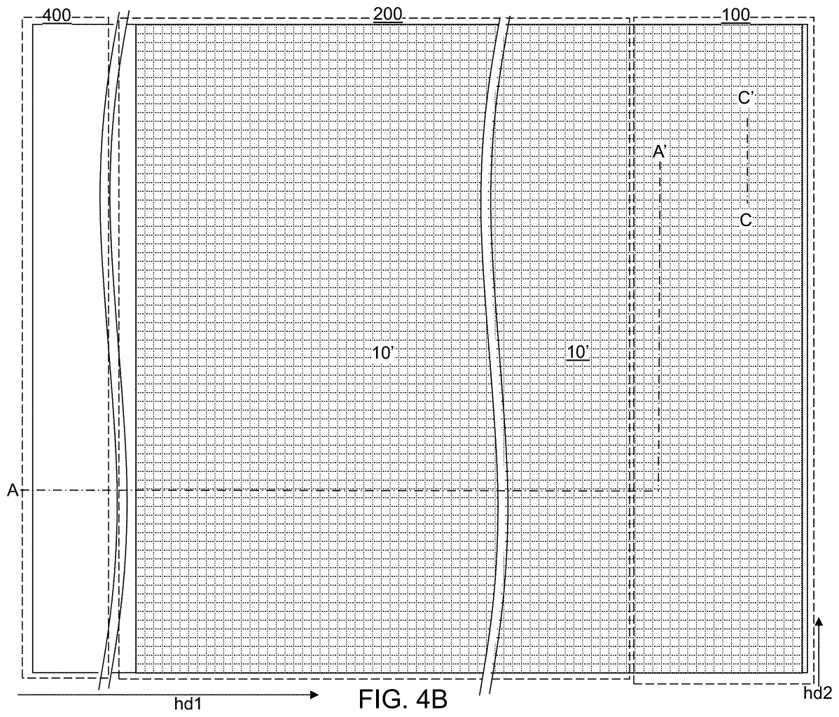

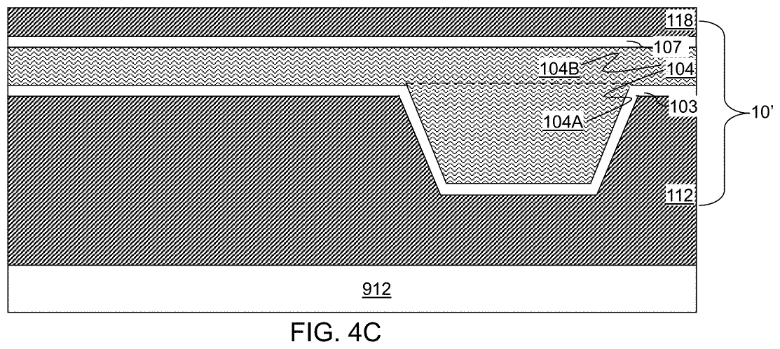

Referring to FIGS. 4A-4C, an upper etch stop dielectric liner 107 may be formed on the sacrificial source-level material layer 104. The upper etch stop dielectric liner 107 may include a dielectric material that is selective to the etch process to be subsequently used to remove the sacrificial source-level material layer 104. In one embodiment, the upper etch stop dielectric liner 107 may include silicon oxide. The thickness of the upper etch stop dielectric liner 107 may be in a range from 2 nm to 10 nm, although lesser and greater thicknesses may also be used.

An upper source layer 118 may be formed over the upper etch stop dielectric liner 107. The upper source layer 118 may include a doped semiconductor material having a doping of the second conductivity type. For example, the upper source layer 118 may include polysilicon or amorphous silicon including dopants of the second conductivity type at an atomic concentration in a range from 1.0×10¹⁹/cm³ to 2.0×10²¹/cm³. The thickness of the upper source layer 118 may be in a range from 5 nm to 30 nm, such as from 7 nm to 15 nm, although lesser and greater thicknesses may also be used.

The layer stack of the lower source layer 112, the lower etch stop dielectric liner 103, the sacrificial source-level material layer 104, the upper etch stop dielectric liner 107, and the upper source layer 118 is herein referred to as in-process source-level material layers 10′, which may be subsequently modified to provide source-level material layers. The in-process source-level material layers 10′ may be lithographically patterned to form an opening in the peripheral region 400 and to form at least one optional opening within the memory array region 100. A dielectric material may be deposited in regions from which portions of the in-process source-level material layers 10′ are removed. The deposited dielectric material may be incorporated into the dielectric isolation layer 912. Thus, the additional portions for the dielectric isolation layer 912 may contact sidewalls of the patterned portions of the in-process source-level material layers 10′.

Generally, the in-process source-level material layers 10′ comprises a lower source layer 112, an optional lower etch stop dielectric liner 103, a sacrificial source-level material layer 104, an optional upper etch stop dielectric liner 107, and an upper source layer 118. The lower source layer 112 comprises a recess trench 209 in which a recessed surface of the lower source layer 112 may be vertically recessed relative to a topmost surface of the lower source layer 112. The sacrificial source-level material layer 104 comprises a sacrificial recess trench fill portion 104A that that protrudes downward and fills the recess region.

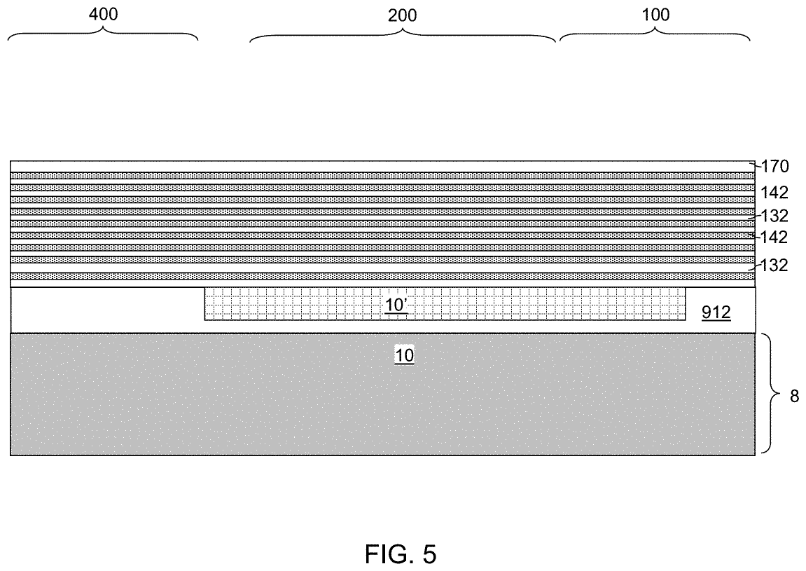

Referring to FIG. 5, an alternating stack of first material layers and second material layers may be subsequently formed. Each first material layer may include a first material, and each second material layer may include a second material that is different from the first material. In embodiments in which at least another alternating stack of material layers is subsequently formed over the alternating stack of the first material layers and the second material layers, the alternating stack is herein referred to as a first-tier alternating stack. The level of the first-tier alternating stack is herein referred to as a first-tier level, and the level of the alternating stack to be subsequently formed immediately above the first-tier level is herein referred to as a second-tier level, etc.

The first-tier alternating stack may include first insulting layers 132 as the first material layers, and first spacer material layers as the second material layers. In one embodiment, the first spacer material layers may be sacrificial material layers that are subsequently replaced with electrically conductive layers. In another embodiment, the first spacer material layers may be electrically conductive layers that are not subsequently replaced with other layers. While the present disclosure is described using embodiments in which sacrificial material layers are replaced with electrically conductive layers, embodiments in which the spacer material layers are formed as electrically conductive layers (thereby obviating the need to perform replacement processes) are expressly contemplated herein.

In one embodiment, the first material layers and the second material layers may be first insulating layers 132 and first sacrificial material layers 142, respectively. In one embodiment, each first insulating layer 132 may include a first insulating material, and each first sacrificial material layer 142 may include a first sacrificial material. An alternating plurality of first insulating layers 132 and first sacrificial material layers 142 may be formed over the in-process source-level material layers 10′. As used herein, a “sacrificial material” refers to a material that is removed during a subsequent processing step.

As used herein, an alternating stack of first elements and second elements refers to a structure in which instances of the first elements and instances of the second elements alternate. Each instance of the first elements that is not an end element of the alternating plurality is adjoined by two instances of the second elements on both sides, and each instance of the second elements that is not an end element of the alternating plurality is adjoined by two instances of the first elements on both ends. The first elements may have the same thickness throughout, or may have different thicknesses. The second elements may have the same thickness throughout, or may have different thicknesses. The alternating plurality of first material layers and second material layers may begin with an instance of the first material layers or with an instance of the second material layers, and may end with an instance of the first material layers or with an instance of the second material layers. In one embodiment, an instance of the first elements and an instance of the second elements may form a unit that is repeated with periodicity within the alternating plurality.

The first-tier alternating stack (132, 142) may include first insulating layers 132 composed of the first material, and first sacrificial material layers 142 composed of the second material, which is different from the first material. The first material of the first insulating layers 132 may be at least one insulating material. Insulating materials that may be used for the first insulating layers 132 include, but are not limited to silicon oxide (including doped or undoped silicate glass), silicon nitride, silicon oxynitride, organosilicate glass (OSG), spin-on dielectric materials, dielectric metal oxides that are commonly known as high dielectric constant (high-k) dielectric oxides (e.g., aluminum oxide, hafnium oxide, etc.) and silicates thereof, dielectric metal oxynitrides and silicates thereof, and organic insulating materials. In one embodiment, the first material of the first insulating layers 132 may be silicon oxide.

The second material of the first sacrificial material layers 142 may be a sacrificial material that is removed selective to the first material of the first insulating layers 132. As used herein, a removal of a first material is “selective to” a second material if the removal process removes the first material at a rate that is at least twice the rate of removal of the second material. The ratio of the rate of removal of the first material to the rate of removal of the second material is herein referred to as a “selectivity” of the removal process for the first material with respect to the second material.

The first sacrificial material layers 142 may comprise an insulating material, a semiconductor material, or a conductive material. The second material of the first sacrificial material layers 142 may be subsequently replaced with electrically conductive electrodes which may function, for example, as control gate electrodes of a vertical NAND device. In one embodiment, the first sacrificial material layers 142 may be material layers that comprise silicon nitride.

In one embodiment, the first insulating layers 132 may include silicon oxide, and sacrificial material layers may include silicon nitride sacrificial material layers. The first material of the first insulating layers 132 may be deposited, for example, by chemical vapor deposition (CVD). For example, if silicon oxide is used for the first insulating layers 132, tetraethylorthosilicate (TEOS) may be used as the precursor material for the CVD process. The second material of the first sacrificial material layers 142 may be formed, for example, CVD or atomic layer deposition (ALD).

The thicknesses of the first insulating layers 132 and the first sacrificial material layers 142 may be in a range from 20 nm to 50 nm, although lesser and greater thicknesses may be used for each first insulating layer 132 and for each first sacrificial material layer 142. The number of repetitions of the pairs of a first insulating layer 132 and a first sacrificial material layer 142 may be in a range from 2 to 1,024, and typically from 8 to 256, although a greater number of repetitions may also be used. In one embodiment, each first sacrificial material layer 142 in the first-tier alternating stack (132, 142) may have a uniform thickness that is substantially invariant within each respective first sacrificial material layer 142.

A first insulating cap layer 170 may be subsequently formed over the first alternating stack (132, 142). The first insulating cap layer 170 may include a dielectric material, which may be any dielectric material that may be used for the first insulating layers 132. In one embodiment, the first insulating cap layer 170 includes the same dielectric material as the first insulating layers 132. The thickness of the first insulating cap layer 170 may be in a range from 20 nm to 300 nm, although lesser and greater thicknesses may also be used.

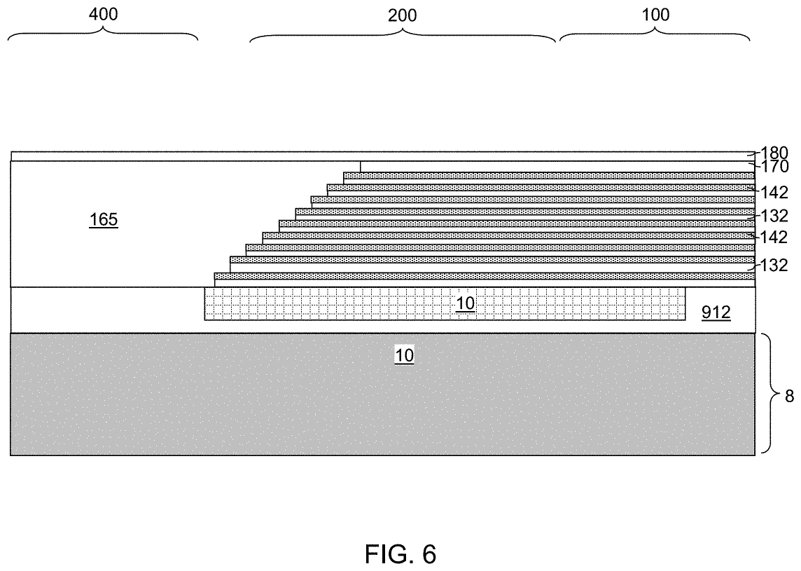

Referring to FIG. 6, the first insulating cap layer 170 and the first-tier alternating stack (132, 142) may be patterned to form first stepped surfaces in the staircase region 200. The staircase region 200 may include a respective first stepped area in which the first stepped surfaces are formed, and a second stepped area in which additional stepped surfaces may be subsequently formed in a second-tier structure (to be subsequently formed over a first-tier structure) and/or additional tier structures. The first stepped surfaces may be formed, for example, by forming a mask layer (not shown) with an opening therein, etching a cavity within the levels of the first insulating cap layer 170, and iteratively expanding the etched area and vertically recessing the cavity by etching each pair of a first insulating layer 132 and a first sacrificial material layer 142 located directly underneath the bottom surface of the etched cavity within the etched area. In one embodiment, top surfaces of the first sacrificial material layers 142 may be physically exposed at the first stepped surfaces. The cavity overlying the first stepped surfaces is herein referred to as a first stepped cavity.

A dielectric fill material (such as undoped silicate glass or doped silicate glass) may be deposited to fill the first stepped cavity. Excess portions of the dielectric fill material may be removed from above the horizontal plane including the top surface of the first insulating cap layer 170. A remaining portion of the dielectric fill material that fills the region overlying the first stepped surfaces constitute a first retro-stepped dielectric material portion 165. As used herein, a “retro-stepped” element refers to an element that has stepped surfaces and a horizontal cross-sectional area that increases monotonically as a function of a vertical distance from a top surface of a substrate on which the element is present. The first-tier alternating stack (132, 142) and the first retro-stepped dielectric material portion 165 collectively constitute a first-tier structure, which is an in-process structure that is subsequently modified.

An inter-tier dielectric layer 180 may be optionally deposited over the first-tier structure (132, 142, 170, 165). The inter-tier dielectric layer 180 includes a dielectric material such as silicon oxide. In one embodiment, the inter-tier dielectric layer 180 may include a doped silicate glass having a greater etch rate than the material of the first insulating layers 132 (which may include an undoped silicate glass). For example, the inter-tier dielectric layer 180 may include phosphosilicate glass. The thickness of the inter-tier dielectric layer 180 may be in a range from 30 nm to 300 nm, although lesser and greater thicknesses may also be used.

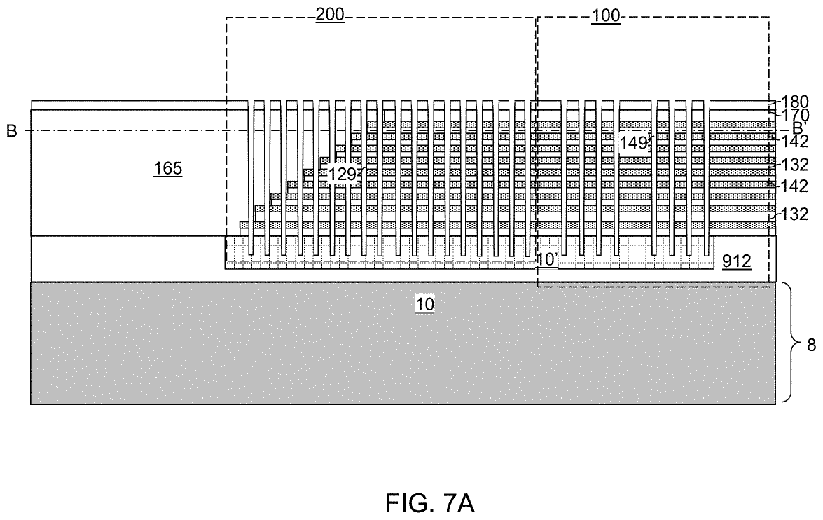

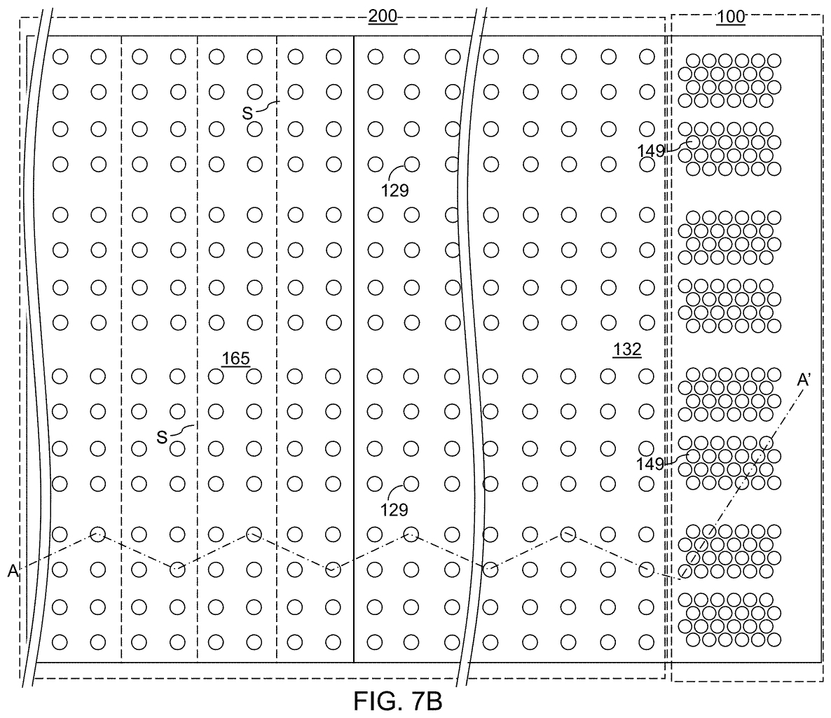

Referring to FIGS. 7A and 7B, various first-tier openings (149, 129) may be formed through the inter-tier dielectric layer 180 and the first-tier structure (132, 142, 170, 165) and into the in-process source-level material layers 10′. The first-tier openings (149, 129) may vertically extend into an upper portion of the lower source layer 112 outside the areas of the sacrificial recess trench fill portions 104A. A photoresist layer (not shown) may be applied over the inter-tier dielectric layer 180, and may be lithographically patterned to form various openings therethrough. The pattern of openings in the photoresist layer may be transferred through the inter-tier dielectric layer 180 and the first-tier structure (132, 142, 170, 165) and into the in-process source-level material layers 10′ by a first anisotropic etch process to form the various first-tier openings (149, 129) concurrently, i.e., during the first isotropic etch process. The various first-tier openings (149, 129) may include first-tier memory openings 149 and first-tier support openings 129. Locations of steps S in the first alternating stack (132, 142) are illustrated as dotted lines in FIG. 7B.

The first-tier memory openings 149 are openings that may be formed in the memory array region 100 through each layer within the first alternating stack (132, 142) and may be subsequently used to form memory stack structures therein. The first-tier memory openings 149 may be formed in clusters of first-tier memory openings 149 that are laterally spaced apart along the second horizontal direction hd2. Each cluster of first-tier memory openings 149 may be formed as a two-dimensional array of first-tier memory openings 149.

The first-tier support openings 129 are openings that may be formed in the staircase region 200, and may subsequently be used to form support pillar structures. A subset of the first-tier support openings 129 that is formed through the first retro-stepped dielectric material portion 165 may be formed through a respective horizontal surface of the first stepped surfaces.

In one embodiment, the first anisotropic etch process may include an initial step in which the materials of the first-tier alternating stack (132, 142) are etched concurrently with the material of the first retro-stepped dielectric material portion 165. The chemistry of the initial etch step may alternate to optimize etching of the first and second materials in the first-tier alternating stack (132, 142) while providing a comparable average etch rate to the material of the first retro-stepped dielectric material portion 165. The first anisotropic etch process may use, for example, a series of reactive ion etch processes or a single reaction etch process (e.g., CF₄/O₂/Ar etch). The sidewalls of the various first-tier openings (149, 129) may be substantially vertical, or may be tapered.

In one embodiment, the terminal portion of the first anisotropic etch process may etch through the upper source layer 118, the upper etch stop dielectric liner 107, the sacrificial source-level material layer 104, and the lower etch stop dielectric liner 103, and at least partly into the lower source layer 112. The terminal portion of the first anisotropic etch process may include at least one etch chemistry for etching the various semiconductor materials of the in-process source-level material layers 10′. The photoresist layer may be subsequently removed, for example, by ashing.

Optionally, the portions of the first-tier memory openings 149 and the first-tier support openings 129 at the level of the inter-tier dielectric layer 180 may be laterally expanded by an isotropic etch. In this case, the inter-tier dielectric layer 180 may comprise a dielectric material (such as borosilicate glass) having a greater etch rate than the first insulating layers 132 (that may include undoped silicate glass) in dilute hydrofluoric acid. An isotropic etch (such as a wet etch using HF) may be used to expand the lateral dimensions of the first-tier memory openings 149 at the level of the inter-tier dielectric layer 180. The portions of the first-tier memory openings 149 located at the level of the inter-tier dielectric layer 180 may be optionally widened to provide a larger landing pad for second-tier memory openings to be subsequently formed through a second-tier alternating stack (to be subsequently formed prior to formation of the second-tier memory openings).

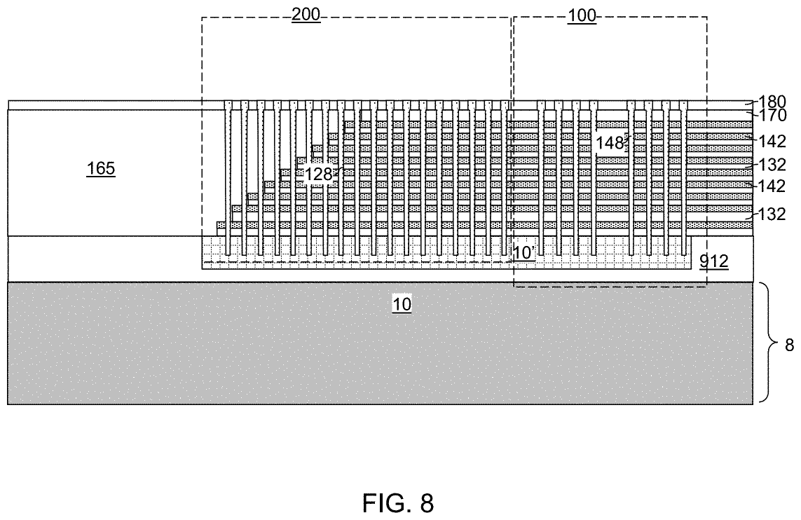

Referring to FIG. 8, sacrificial first-tier opening fill portions (148, 128) may be formed in the various first-tier openings (149, 129). For example, a sacrificial first-tier fill material may be concurrently deposited in each of the first-tier openings (149, 129). The sacrificial first-tier fill material may include a material that may be subsequently removed selective to the materials of the first insulating layers 132 and the first sacrificial material layers 142.

In one embodiment, the sacrificial first-tier fill material may include a semiconductor material such as silicon (e.g., a-Si or polysilicon), a silicon-germanium alloy, germanium, a III-V compound semiconductor material, or a combination thereof. Optionally, a thin etch stop liner (such as a silicon oxide layer or a silicon nitride layer having a thickness in a range from 1 nm to 3 nm) may be used prior to depositing the sacrificial first-tier fill material. The sacrificial first-tier fill material may be formed by a non-conformal deposition or a conformal deposition method.

In another embodiment, the sacrificial first-tier fill material may include a silicon oxide material having a higher etch rate than the materials of the first insulating layers 132, the first insulating cap layer 170, and the inter-tier dielectric layer 180. For example, the sacrificial first-tier fill material may include borosilicate glass or porous or non-porous organosilicate glass having an etch rate that is at least 100 times higher than the etch rate of densified TEOS oxide (i.e., a silicon oxide material formed by decomposition of tetraethylorthosilicate glass in a chemical vapor deposition process and subsequently densified in an anneal process) in a 100:1 dilute hydrofluoric acid. In this case, a thin etch stop liner (such as a silicon nitride layer having a thickness in a range from 1 nm to 3 nm) may be used prior to depositing the sacrificial first-tier fill material. The sacrificial first-tier fill material may be formed by a non-conformal deposition or a conformal deposition method.

In yet another embodiment, the sacrificial first-tier fill material may include amorphous silicon or a carbon-containing material (such as amorphous carbon or diamond-like carbon) that may be subsequently removed by ashing, or a silicon-based polymer that may be subsequently removed selective to the materials of the first alternating stack (132, 142).

Portions of the deposited sacrificial material may be removed from above the topmost layer of the first-tier alternating stack (132, 142), such as from above the inter-tier dielectric layer 180. For example, the sacrificial first-tier fill material may be recessed to a top surface of the inter-tier dielectric layer 180 using a planarization process. The planarization process may include a recess etch, chemical mechanical planarization (CMP), or a combination thereof. The top surface of the inter-tier dielectric layer 180 may be used as an etch stop layer or a planarization stop layer.

Remaining portions of the sacrificial first-tier fill material comprise sacrificial first-tier opening fill portions (148, 128). Specifically, each remaining portion of the sacrificial material in a first-tier memory opening 149 may constitute a sacrificial first-tier memory opening fill portion 148. Each remaining portion of the sacrificial material in a first-tier support opening 129 may constitute a sacrificial first-tier support opening fill portion 128. The various sacrificial first-tier opening fill portions (148, 128) may be concurrently formed, i.e., during a same set of processes including the deposition process that deposits the sacrificial first-tier fill material and the planarization process that removes the first-tier deposition process from above the first alternating stack (132, 142) (such as from above the top surface of the inter-tier dielectric layer 180). The top surfaces of the sacrificial first-tier opening fill portions (148, 128) may be coplanar with the top surface of the inter-tier dielectric layer 180. Each of the sacrificial first-tier opening fill portions (148, 128) may, or may not, include cavities therein.

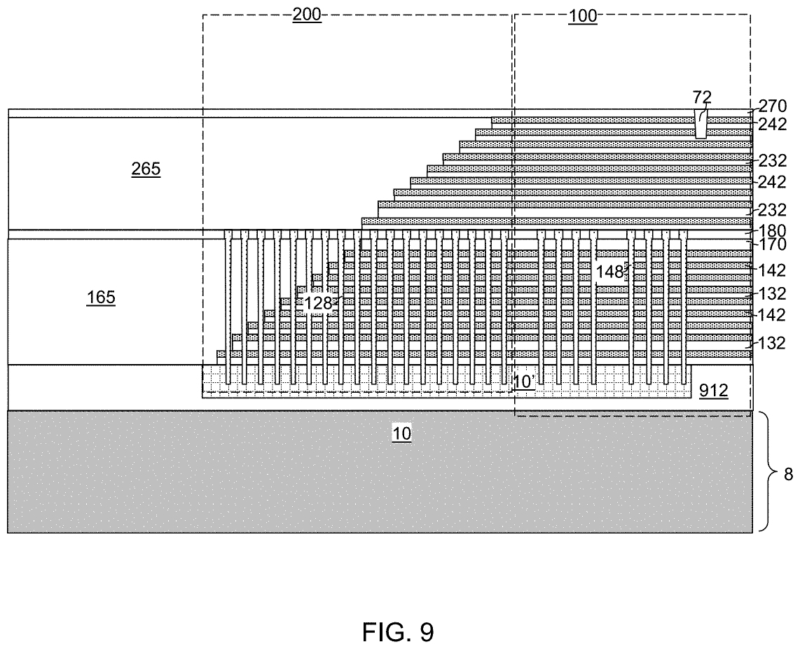

Referring to FIG. 9, a second-tier structure may be formed over the first-tier structure (132, 142, 170, 148). The second-tier structure may include an additional alternating stack of insulating layers and spacer material layers, which may be sacrificial material layers. For example, a second alternating stack (232, 242) of material layers may be subsequently formed on the top surface of the first alternating stack (132, 142). The second alternating stack (232, 242) may include an alternating plurality of third material layers and fourth material layers. Each third material layer may include a third material, and each fourth material layer may include a fourth material that is different from the third material. In one embodiment, the third material may be the same as the first material of the first insulating layer 132, and the fourth material may be the same as the second material of the first sacrificial material layers 142.

In one embodiment, the third material layers may be second insulating layers 232 and the fourth material layers may be second spacer material layers that provide vertical spacing between each vertically neighboring pair of the second insulating layers 232. In one embodiment, the third material layers and the fourth material layers may be second insulating layers 232 and second sacrificial material layers 242, respectively. The third material of the second insulating layers 232 may be at least one insulating material. The fourth material of the second sacrificial material layers 242 may be a sacrificial material that may be removed selective to the third material of the second insulating layers 232. The second sacrificial material layers 242 may comprise an insulating material, a semiconductor material, or a conductive material. The fourth material of the second sacrificial material layers 242 may be subsequently replaced with electrically conductive electrodes which may function, for example, as control gate electrodes of a vertical NAND device.

In one embodiment, each second insulating layer 232 may include a second insulating material, and each second sacrificial material layer 242 may include a second sacrificial material. In this case, the second alternating stack (232, 242) may include an alternating plurality of second insulating layers 232 and second sacrificial material layers 242. The third material of the second insulating layers 232 may be deposited, for example, by chemical vapor deposition (CVD). The fourth material of the second sacrificial material layers 242 may be formed, for example, CVD or atomic layer deposition (ALD).

The third material of the second insulating layers 232 may be at least one insulating material. Insulating materials that may be used for the second insulating layers 232 may be any material that may be used for the first insulating layers 132. The fourth material of the second sacrificial material layers 242 may be a sacrificial material that is removed selective to the third material of the second insulating layers 232. Sacrificial materials that may be used for the second sacrificial material layers 242 may be any material that may be used for the first sacrificial material layers 142. In one embodiment, the second insulating material may be the same as the first insulating material, and the second sacrificial material may be the same as the first sacrificial material.

The thicknesses of the second insulating layers 232 and the second sacrificial material layers 242 may be in a range from 20 nm to 50 nm, although lesser and greater thicknesses may be used for each second insulating layer 232 and for each second sacrificial material layer 242. The number of repetitions of the pairs of a second insulating layer 232 and a second sacrificial material layer 242 may be in a range from 2 to 1,024, and typically from 8 to 256, although a greater number of repetitions may also be used. In one embodiment, each second sacrificial material layer 242 in the second alternating stack (232, 242) may have a uniform thickness that is substantially invariant within each respective second sacrificial material layer 242.

Second stepped surfaces in the second stepped area may be formed in the staircase region 200 using a same set of processing steps as the processing steps used to form the first stepped surfaces in the first stepped area with suitable adjustment to the pattern of at least one masking layer. A second retro-stepped dielectric material portion 265 may be formed over the second stepped surfaces in the staircase region 200.

A second insulating cap layer 270 may be subsequently formed over the second alternating stack (232, 242). The second insulating cap layer 270 includes a dielectric material that is different from the material of the second sacrificial material layers 242. In one embodiment, the second insulating cap layer 270 may include silicon oxide. In one embodiment, the first and second sacrificial material layers (142, 242) may comprise silicon nitride.

Generally speaking, at least one alternating stack of insulating layers (132, 232) and spacer material layers (such as sacrificial material layers (142, 242)) may be formed over the in-process source-level material layers 10′, and at least one retro-stepped dielectric material portion (165, 265) may be formed over the staircase regions on the at least one alternating stack (132, 142, 232, 242).

Optionally, drain-select-level isolation structures 72 may be formed through a subset of layers in an upper portion of the second-tier alternating stack (232, 242). The second sacrificial material layers 242 that are cut by the drain-select-level isolation structures 72 correspond to the levels in which drain-select-level electrically conductive layers are subsequently formed. The drain-select-level isolation structures 72 include a dielectric material such as silicon oxide. The drain-select-level isolation structures 72 may laterally extend along a first horizontal direction hd1, and may be laterally spaced apart along a second horizontal direction hd2 that is perpendicular to the first horizontal direction hd1. The combination of the second alternating stack (232, 242), the second retro-stepped dielectric material portion 265, the second insulating cap layer 270, and the optional drain-select-level isolation structures 72 collectively constitute a second-tier structure (232, 242, 265, 270, 72).

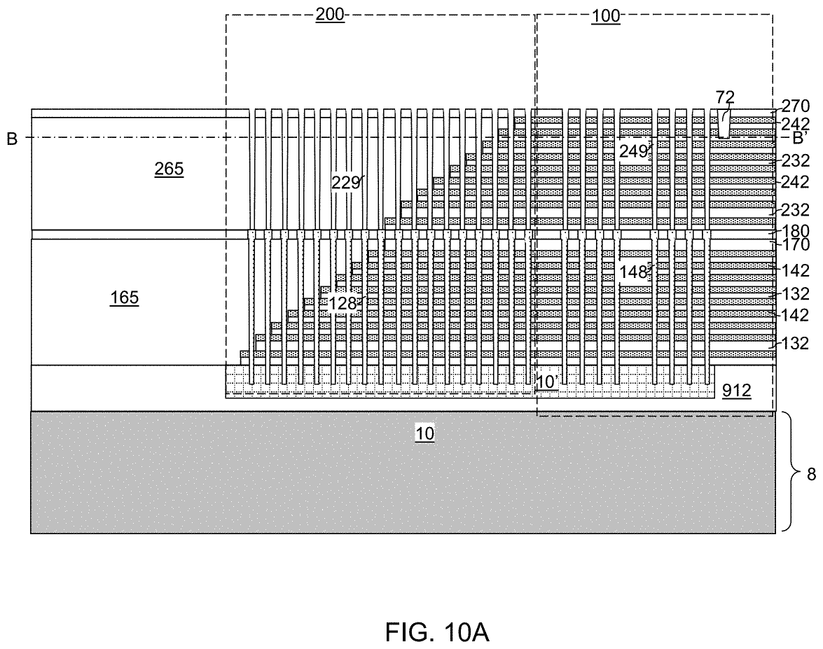

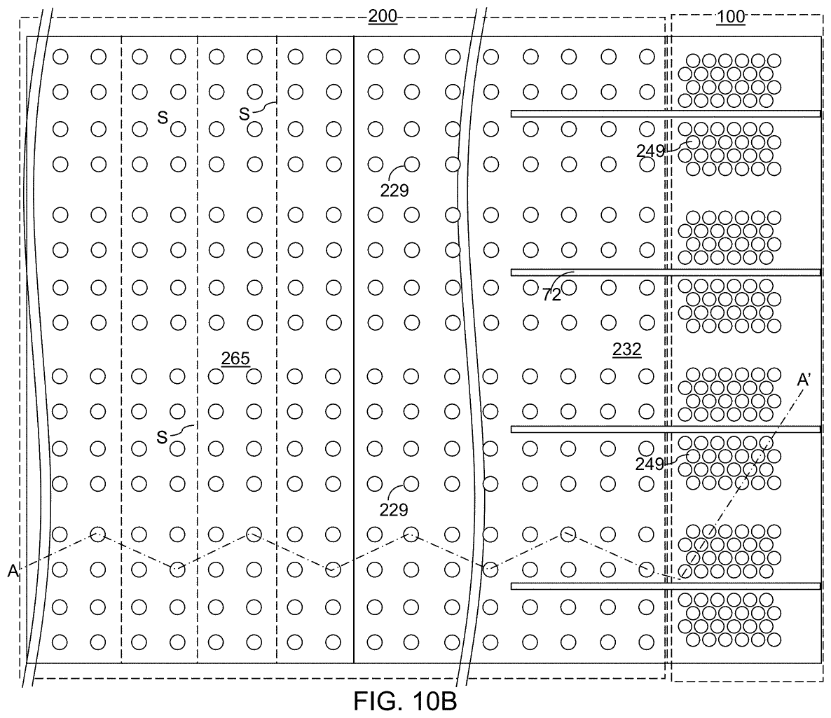

Referring to FIGS. 10A and 10B, various second-tier openings (249, 229) may be formed through the second-tier structure (232, 242, 265, 270, 72). A photoresist layer (not shown) may be applied over the second insulating cap layer 270, and may be lithographically patterned to form various openings therethrough. The pattern of the openings may be the same as the pattern of the various first-tier openings (149, 129), which is the same as the sacrificial first-tier opening fill portions (148, 128). Thus, the lithographic mask used to pattern the first-tier openings (149, 129) may be used to pattern the photoresist layer.

The pattern of openings in the photoresist layer may be transferred through the second-tier structure (232, 242, 265, 270, 72) by a second anisotropic etch process to form various second-tier openings (249, 229) concurrently, i.e., during the second anisotropic etch process. The various second-tier openings (249, 229) may include second-tier memory openings 249 and second-tier support openings 229.

The second-tier memory openings 249 may be formed directly on a top surface of a respective one of the sacrificial first-tier memory opening fill portions 148. The second-tier support openings 229 may be formed directly on a top surface of a respective one of the sacrificial first-tier support opening fill portions 128. Further, each second-tier support openings 229 may be formed through a horizontal surface within the second stepped surfaces, which include the interfacial surfaces between the second alternating stack (232, 242) and the second retro-stepped dielectric material portion 265. Locations of steps S in the first-tier alternating stack (132, 142) and the second-tier alternating stack (232, 242) are illustrated as dotted lines in FIG. 7B.

The second anisotropic etch process may include an etch step in which the materials of the second-tier alternating stack (232, 242) are etched concurrently with the material of the second retro-stepped dielectric material portion 265. The chemistry of the etch step may alternate to optimize etching of the materials in the second-tier alternating stack (232, 242) while providing a comparable average etch rate to the material of the second retro-stepped dielectric material portion 265. The second anisotropic etch process may use, for example, a series of reactive ion etch processes or a single reaction etch process (e.g., CF₄/O₂/Ar etch). The sidewalls of the various second-tier openings (249, 229) may be substantially vertical, or may be tapered. A bottom periphery of each second-tier opening (249, 229) may be laterally offset, and/or may be located entirely within, a periphery of a top surface of an underlying sacrificial first-tier opening fill portion (148, 128). The photoresist layer may be subsequently removed, for example, by ashing.

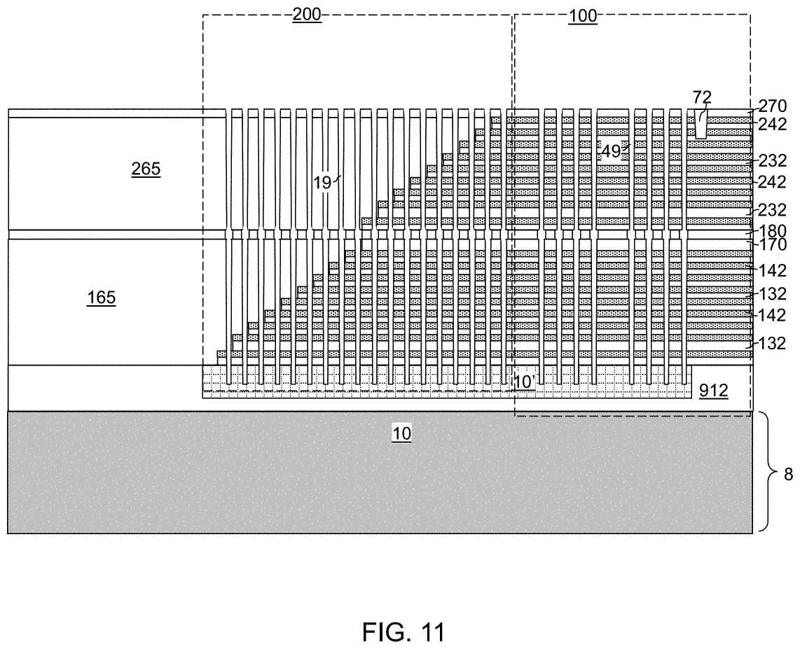

Referring to FIG. 11, the sacrificial first-tier fill material of the sacrificial first-tier opening fill portions (148, 128) may be removed using an etch process that etches the sacrificial first-tier fill material selective to the materials of the first and second insulating layers (132, 232), the first and second sacrificial material layers (142,242), the first and second insulating cap layers (170, 270), and the inter-tier dielectric layer 180. A memory opening 49, which is also referred to as an inter-tier memory opening 49, may be formed in each combination of a second-tier memory openings 249 and a volume from which a sacrificial first-tier memory opening fill portion 148 is removed. A support opening 19, which is also referred to as an inter-tier support opening 19, may be formed in each combination of a second-tier support openings 229 and a volume from which a sacrificial first-tier support opening fill portion 128 is removed.

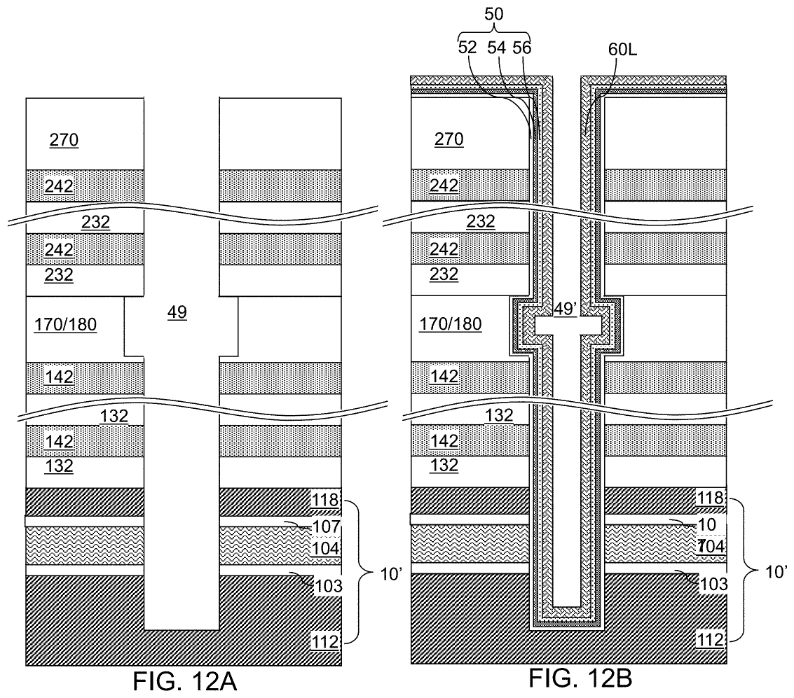

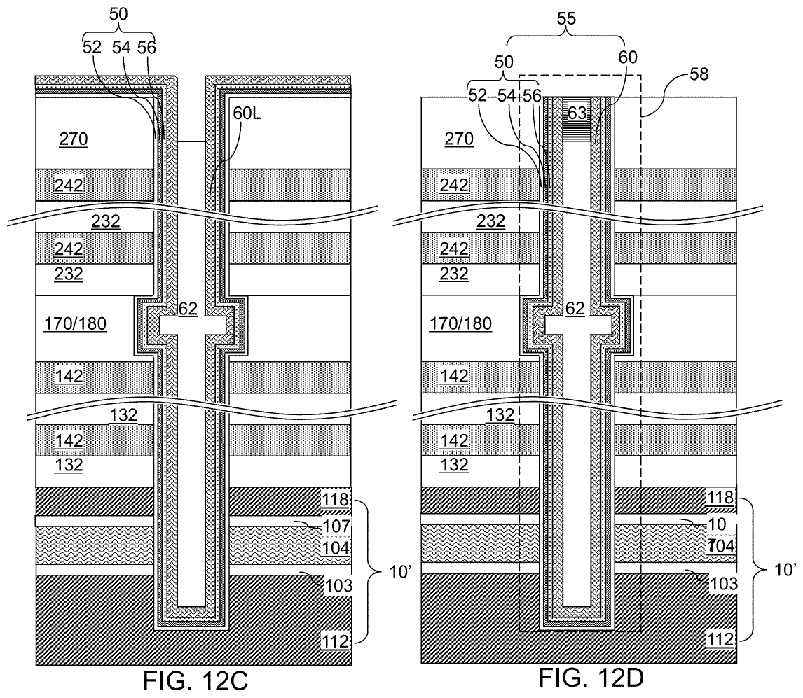

FIGS. 12A-12D provide sequential cross-sectional views of a memory opening 49 during formation of a memory opening fill structure. The same structural change occurs in each of the memory openings 49 and the support openings 19.

Referring to FIG. 12A, a memory opening 49 in the exemplary device structure of FIG. 11 is illustrated. The memory opening 49 extends through the first-tier structure and the second-tier structure.

Referring to FIG. 12B, a stack of layers including a blocking dielectric layer 52, a charge storage layer 54, a tunneling dielectric layer 56, and a semiconductor channel material layer 60L may be sequentially deposited in the memory openings 49. The blocking dielectric layer 52 may include a single dielectric material layer or a stack of a plurality of dielectric material layers. In one embodiment, the blocking dielectric layer may include a dielectric metal oxide layer consisting essentially of a dielectric metal oxide. As used herein, a dielectric metal oxide refers to a dielectric material that includes at least one metallic element and at least oxygen. The dielectric metal oxide may consist essentially of the at least one metallic element and oxygen, or may consist essentially of the at least one metallic element, oxygen, and at least one non-metallic element such as nitrogen. In one embodiment, the blocking dielectric layer 52 may include a dielectric metal oxide having a dielectric constant greater than 7.9, i.e., having a dielectric constant greater than the dielectric constant of silicon nitride. The thickness of the dielectric metal oxide layer may be in a range from 1 nm to 20 nm, although lesser and greater thicknesses may also be used. The dielectric metal oxide layer may subsequently function as a dielectric material portion that blocks leakage of stored electrical charges to control gate electrodes. In one embodiment, the blocking dielectric layer 52 includes aluminum oxide. Alternatively, or additionally, the blocking dielectric layer 52 may include a dielectric semiconductor compound such as silicon oxide, silicon oxynitride, silicon nitride, or a combination thereof.

Subsequently, the charge storage layer 54 may be formed. In one embodiment, the charge storage layer 54 may be a continuous layer or patterned discrete portions of a charge trapping material including a dielectric charge trapping material, which may be, for example, silicon nitride. Alternatively, the charge storage layer 54 may include a continuous layer or patterned discrete portions of a conductive material such as doped polysilicon or a metallic material that is patterned into multiple electrically isolated portions (e.g., floating gates), for example, by being formed within lateral recesses into sacrificial material layers (142, 242). In one embodiment, the charge storage layer 54 includes a silicon nitride layer. In one embodiment, the sacrificial material layers (142, 242) and the insulating layers (132, 232) may have vertically coincident sidewalls, and the charge storage layer 54 may be formed as a single continuous layer. Alternatively, the sacrificial material layers (142, 242) may be laterally recessed with respect to the sidewalls of the insulating layers (132, 232), and a combination of a deposition process and an anisotropic etch process may be used to form the charge storage layer 54 as a plurality of memory material portions that are vertically spaced apart. The thickness of the charge storage layer 54 may be in a range from 2 nm to 20 nm, although lesser and greater thicknesses may also be used.

The tunneling dielectric layer 56 may include a dielectric material through which charge tunneling may be performed under suitable electrical bias conditions. The charge tunneling may be performed through hot-carrier injection or by Fowler-Nordheim tunneling induced charge transfer depending on the mode of operation of the monolithic three-dimensional NAND string memory device to be formed. The tunneling dielectric layer 56 may include silicon oxide, silicon nitride, silicon oxynitride, dielectric metal oxides (such as aluminum oxide and hafnium oxide), dielectric metal oxynitride, dielectric metal silicates, alloys thereof, and/or combinations thereof. In one embodiment, the tunneling dielectric layer 56 may include a stack of a first silicon oxide layer, a silicon oxynitride layer, and a second silicon oxide layer, which is commonly known as an ONO stack. In one embodiment, the tunneling dielectric layer 56 may include a silicon oxide layer that is substantially free of carbon or a silicon oxynitride layer that is substantially free of carbon. The thickness of the tunneling dielectric layer 56 may be in a range from 2 nm to 20 nm, although lesser and greater thicknesses may also be used. The stack of the blocking dielectric layer 52, the charge storage layer 54, and the tunneling dielectric layer 56 constitutes a memory film 50 that stores memory bits.

The semiconductor channel material layer 60L may include a p-doped semiconductor material such as at least one elemental semiconductor material, at least one III-V compound semiconductor material, at least one II-VI compound semiconductor material, at least one organic semiconductor material, or other semiconductor materials known in the art. In one embodiment, the semiconductor channel material layer 60L may having a uniform doping. In one embodiment, the semiconductor channel material layer 60L has a p-type doping in which p-type dopants (such as boron atoms) are present at an atomic concentration in a range from 1.0×10¹²/cm³ to 1.0×10¹⁸/cm³, such as from 1.0×10¹⁴/cm³ to 1.0×10¹⁷/cm³. In one embodiment, the semiconductor channel material layer 60L includes, and/or consists essentially of, boron-doped amorphous silicon or boron-doped polysilicon. In another embodiment, the semiconductor channel material layer 60L has an n-type doping in which n-type dopants (such as phosphor atoms or arsenic atoms) are present at an atomic concentration in a range from 1.0×10¹²/cm³ to 1.0×10¹⁸/cm³, such as from 1.0×10¹⁴/cm³ to 1.0×10¹⁷/cm³. The semiconductor channel material layer 60L may be formed by a conformal deposition method such as low pressure chemical vapor deposition (LPCVD). The thickness of the semiconductor channel material layer 60L may be in a range from 2 nm to 10 nm, although lesser and greater thicknesses may also be used. A cavity 49′ is formed in the volume of each memory opening 49 that is not filled with the deposited material layers (52, 54, 56, 60L).

Referring to FIG. 12C, in case the cavity 49′ in each memory opening is not completely filled by the semiconductor channel material layer 60L, a dielectric core layer may be deposited in the cavity 49′ to fill any remaining portion of the cavity 49′ within each memory opening. The dielectric core layer includes a dielectric material such as silicon oxide or organosilicate glass. The dielectric core layer may be deposited by a conformal deposition method such as low pressure chemical vapor deposition (LPCVD), or by a self-planarizing deposition process such as spin coating. The horizontal portion of the dielectric core layer overlying the second insulating cap layer 270 may be removed, for example, by a recess etch. The recess etch continues until top surfaces of the remaining portions of the dielectric core layer are recessed to a height between the top surface of the second insulating cap layer 270 and the bottom surface of the second insulating cap layer 270. Each remaining portion of the dielectric core layer constitutes a dielectric core 62.

Referring to FIG. 12D, a doped semiconductor material having a doping of a second conductivity type may be deposited in cavities overlying the dielectric cores 62. The second conductivity type is the opposite of the first conductivity type. For example, if the first conductivity type is p-type, the second conductivity type is n-type, and vice versa. Portions of the deposited doped semiconductor material, the semiconductor channel material layer 60L, the tunneling dielectric layer 56, the charge storage layer 54, and the blocking dielectric layer 52 that overlie the horizontal plane including the top surface of the second insulating cap layer 270 may be removed by a planarization process such as a chemical mechanical planarization (CMP) process.

Each remaining portion of the doped semiconductor material of the second conductivity type constitutes a drain region 63. The dopant concentration in the drain regions 63 may be in a range from 5.0×10¹⁹/cm³ to 2.0×10²¹/cm³, although lesser and greater dopant concentrations may also be used. The doped semiconductor material may be, for example, doped polysilicon.

Each remaining portion of the semiconductor channel material layer 60L constitutes a vertical semiconductor channel 60 through which electrical current may flow when a vertical NAND device including the vertical semiconductor channel 60 is turned on. A tunneling dielectric layer 56 is surrounded by a charge storage layer 54, and laterally surrounds a vertical semiconductor channel 60. Each adjoining set of a blocking dielectric layer 52, a charge storage layer 54, and a tunneling dielectric layer 56 collectively constitute a memory film 50, which may store electrical charges with a macroscopic retention time. In some embodiments, a blocking dielectric layer 52 may not be present in the memory film 50 at this step, and a blocking dielectric layer may be subsequently formed after formation of backside recesses. As used herein, a macroscopic retention time refers to a retention time suitable for operation of a memory device as a permanent memory device such as a retention time in excess of 24 hours.

Each combination of a memory film 50 and a vertical semiconductor channel 60 (which is a vertical semiconductor channel) within a memory opening 49 constitutes a memory stack structure 55. The memory stack structure 55 is a combination of a vertical semiconductor channel 60, a tunneling dielectric layer 56, a plurality of memory elements comprising portions of the charge storage layer 54, and an optional blocking dielectric layer 52. Each combination of a memory stack structure 55, a dielectric core 62, and a drain region 63 within a memory opening 49 constitutes a memory opening fill structure 58. The in-process source-level material layers 10′, the first-tier structure (132, 142, 170, 165), the second-tier structure (232, 242, 270, 265, 72), the inter-tier dielectric layer 180, and the memory opening fill structures 58 collectively constitute a memory-level assembly.

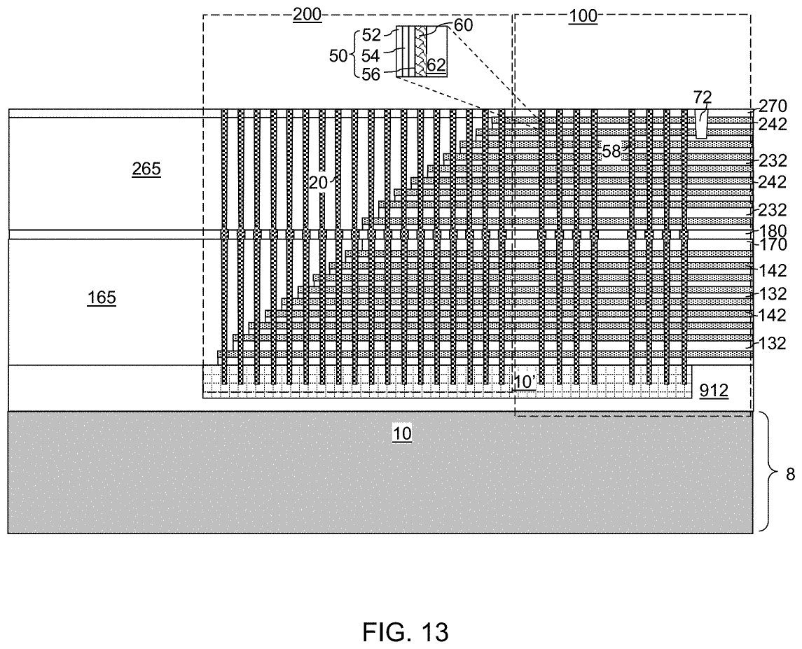

Referring to FIG. 13, the exemplary structure is illustrated after formation of the memory opening fill structures 58. Support pillar structures 20 may be formed in the support openings 19 concurrently with formation of the memory opening fill structures 58. Each support pillar structure 20 may have a same set of components as a memory opening fill structure 58.

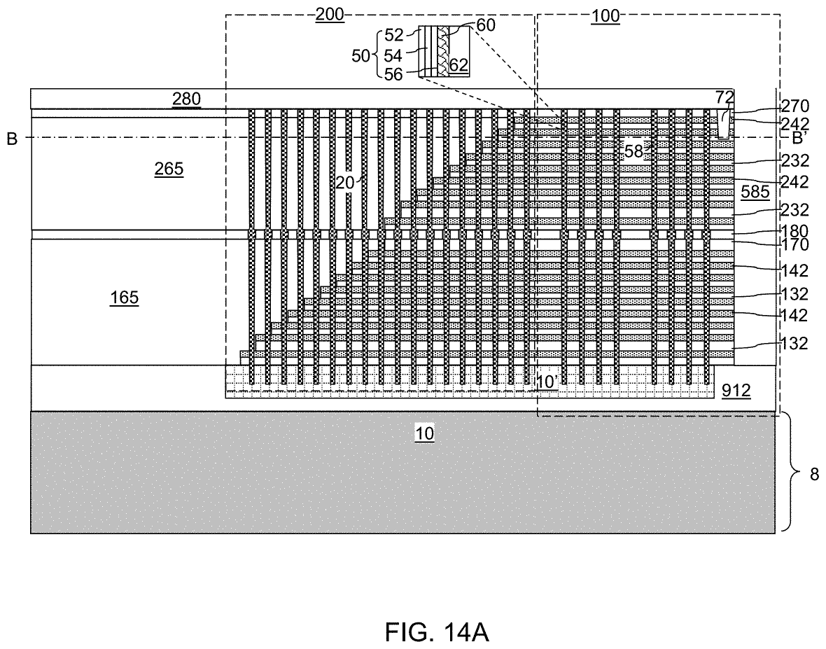

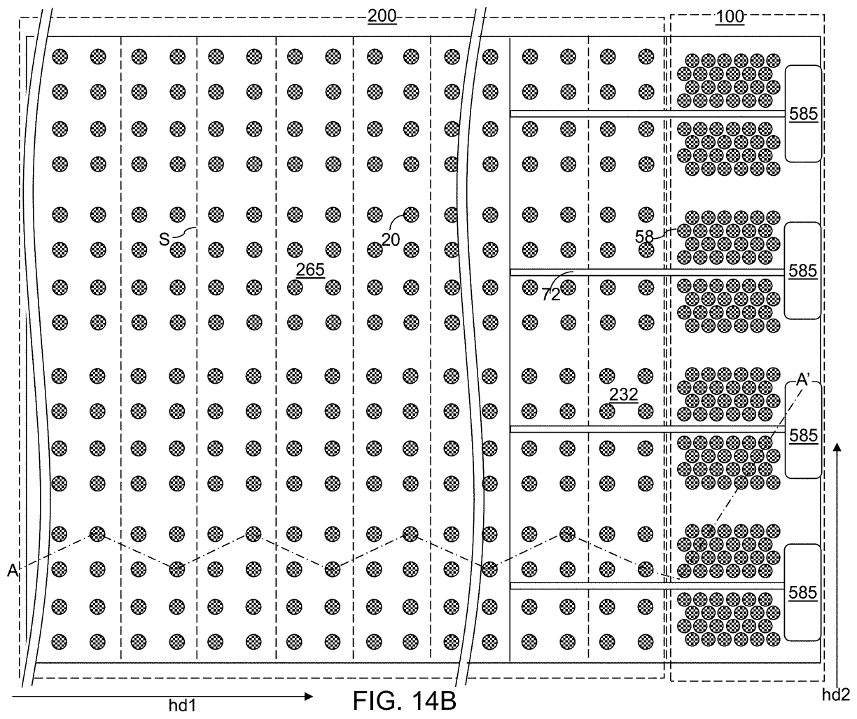

Referring to FIGS. 14A and 14B, a first contact level dielectric layer 280 may be formed over the second-tier structure (232, 242, 270, 265, 72). The first contact level dielectric layer 280 may include a dielectric material such as silicon oxide, and may be formed by a conformal or non-conformal deposition process. For example, the first contact level dielectric layer 280 may include undoped silicate glass and may have a thickness in a range from 100 nm to 600 nm, although lesser and greater thicknesses may also be used.

A photoresist layer (not shown) may be applied over the first contact level dielectric layer 280, and may be lithographically patterned to form discrete openings within the area of the memory array region 100 in which memory opening fill structures 58 are not present. An anisotropic etch may be performed to form vertical interconnection region cavities 585 having substantially vertical sidewalls that extend through the first contact level dielectric layer 280, the second-tier structure (232, 242, 270, 265, 72), and the first-tier structure (132, 142, 170, 165) may be formed underneath the openings in the photoresist layer. The photoresist layer may be removed, for example, by ashing.

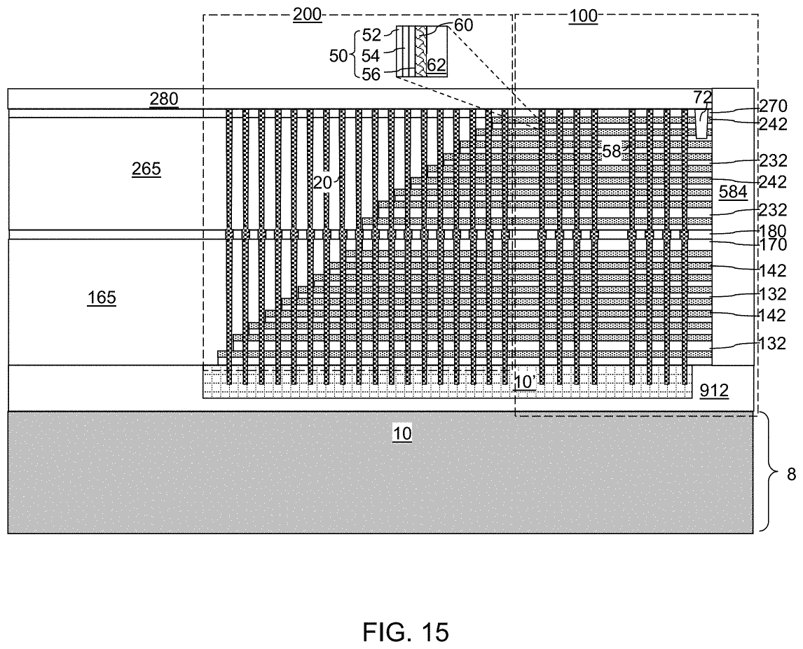

Referring to FIG. 15, a dielectric material such as silicon oxide may be deposited in the vertical interconnection region cavities 585 by a conformal deposition process (such as low pressure chemical vapor deposition) or a self-planarizing deposition process (such as spin coating). Excess portions of the deposited dielectric material may be removed from above the top surface of the first contact level dielectric layer 280 by a planarization process. Remaining portions of the dielectric material in the vertical interconnection region cavities 585 constitute interconnection region dielectric fill material portions 584.

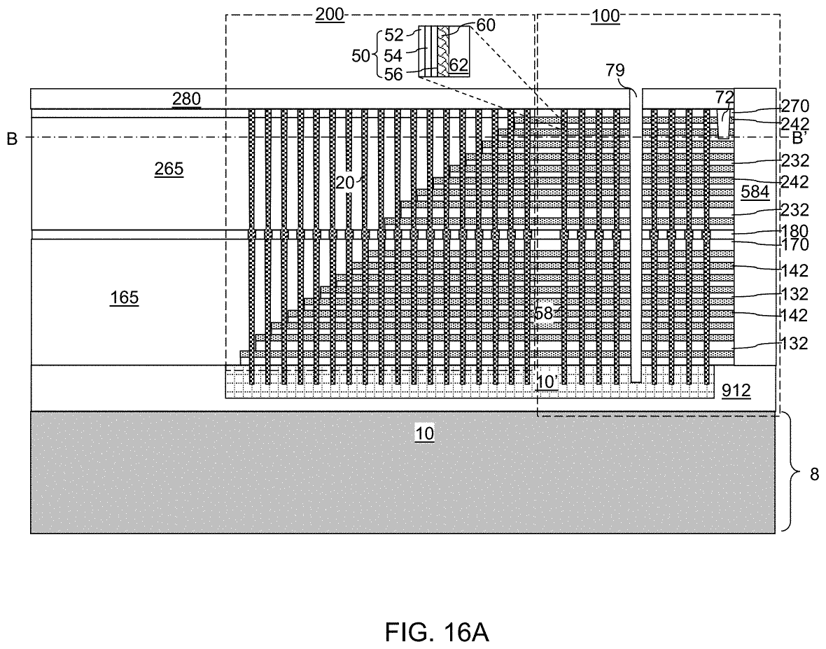

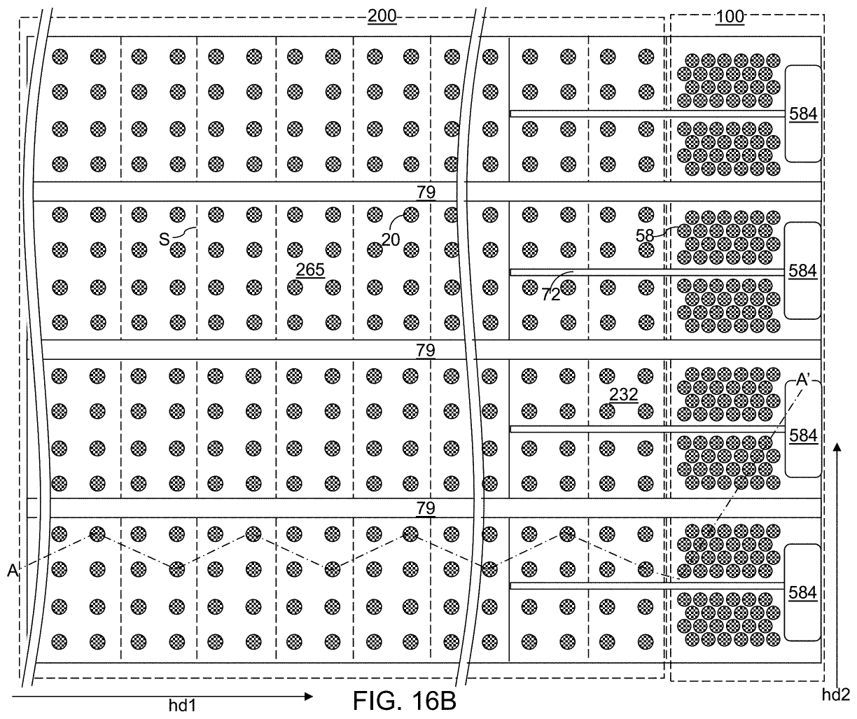

Referring to FIGS. 16A and 16B, a photoresist layer may be applied over the first contact level dielectric layer 280 and may be lithographically patterned to form elongated openings that extend along the first horizontal direction hd1 between clusters of memory opening fill structures 58. Backside trenches 79 may be formed by transferring the pattern in the photoresist layer (not shown) through the first contact level dielectric layer 280, the second-tier structure (232, 242, 270, 265, 72), and the first-tier structure (132, 142, 170, 165), and into the in-process source-level material layers 10′. Portions of the first contact level dielectric layer 280, the second-tier structure (232, 242, 270, 265, 72), the first-tier structure (132, 142, 170, 165), and the in-process source-level material layers 10′ that underlie the openings in the photoresist layer may be removed to form the backside trenches 79. In one embodiment, the backside trenches 79 may be formed between clusters of memory stack structures 55. The clusters of the memory stack structures 55 may be laterally spaced apart along the second horizontal direction hd2 by the backside trenches 79.

The upper source layer 118 may be used as an endpoint detection layer during the anisotropic etch process that forms the backside trenches. In one embodiment, the anisotropic etch process may include an etch step that etches materials of the alternating stack (132, 142) selective to the doped semiconductor material of the upper source layer 118. Subsequently, the upper source layer 118 may be etched through using the upper etch stop dielectric liner 107 as an etch stop layer. The upper etch stop dielectric liner 107 may be subsequently etched through using an etch chemistry that is selective to the material of the sacrificial source-level material layer 104. The backside trenches 79 may be formed within areas in which the sacrificial recess trench fill portions 104A are present. The sacrificial recess trench fill portions 104A provide protection against process variations in which the depth of the backside trenches 79 exceeds a target depth. Specifically, the additional thickness of the sacrificial source-level material layer 104 provided by the sacrificial recess trench fill portions 104A prevents extension of the bottom portions of the backside trenches 79 into the lower source layer 112. Generally, each backside trench 79 may be formed through the alternating stack (132, 142) such that a bottom surface of each backside trench 79 is formed within an area of a recess trench in the lower source layer 112. The bottom surface of each backside trench 79 may be formed between a top surface of the sacrificial source-level material layer 104 and the recessed surface of the lower source layer 112.

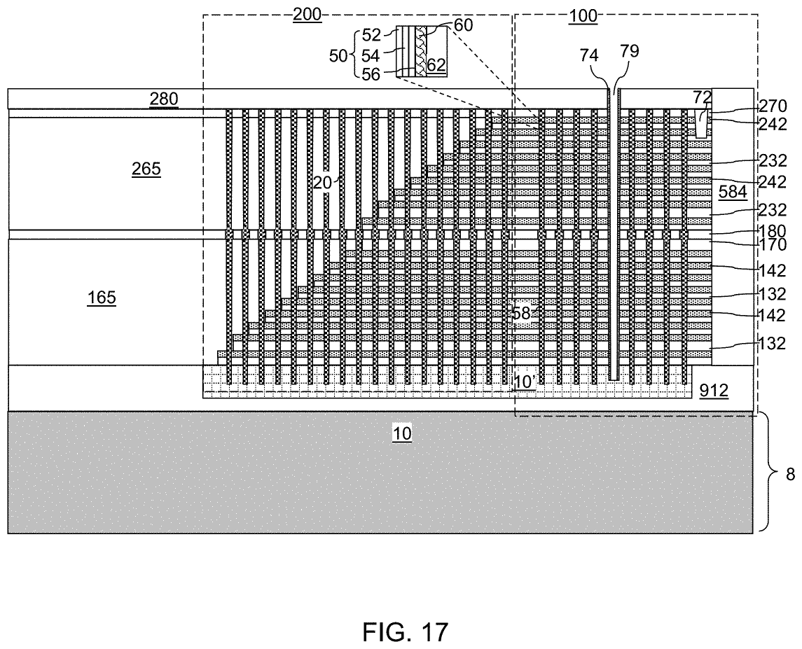

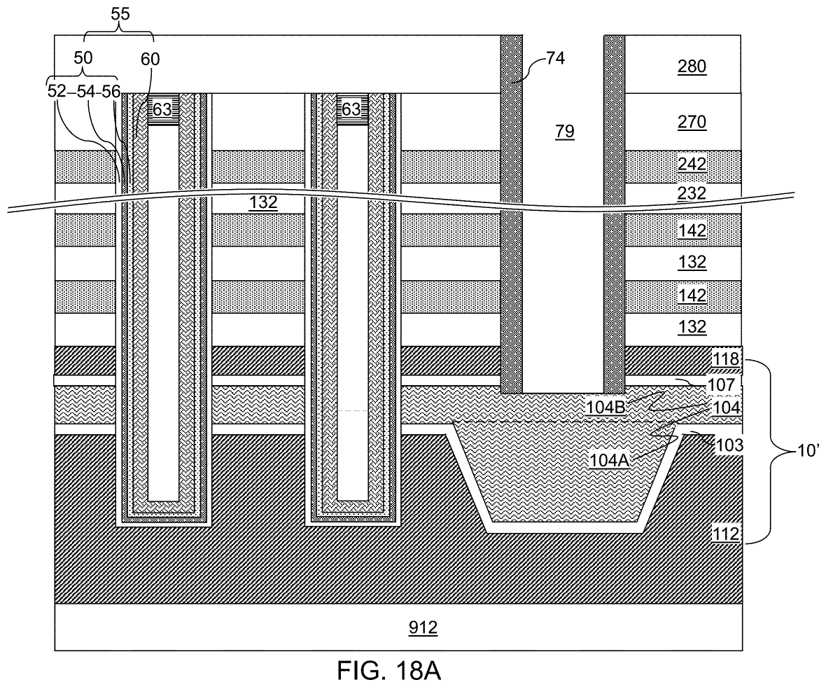

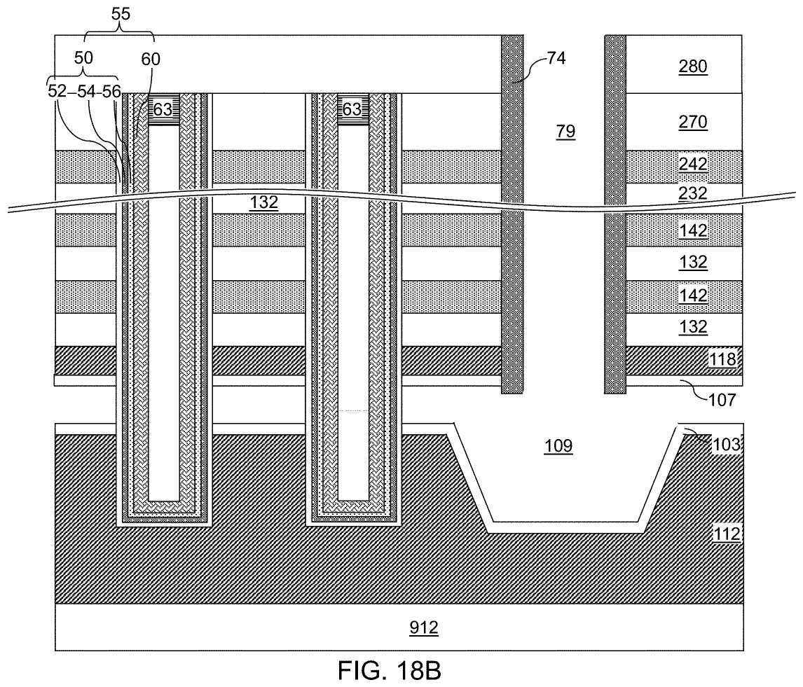

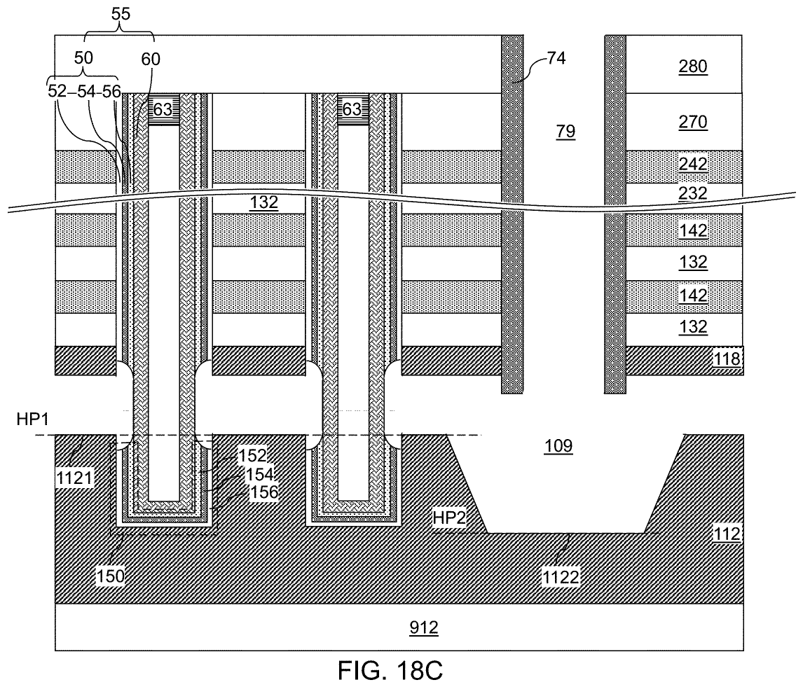

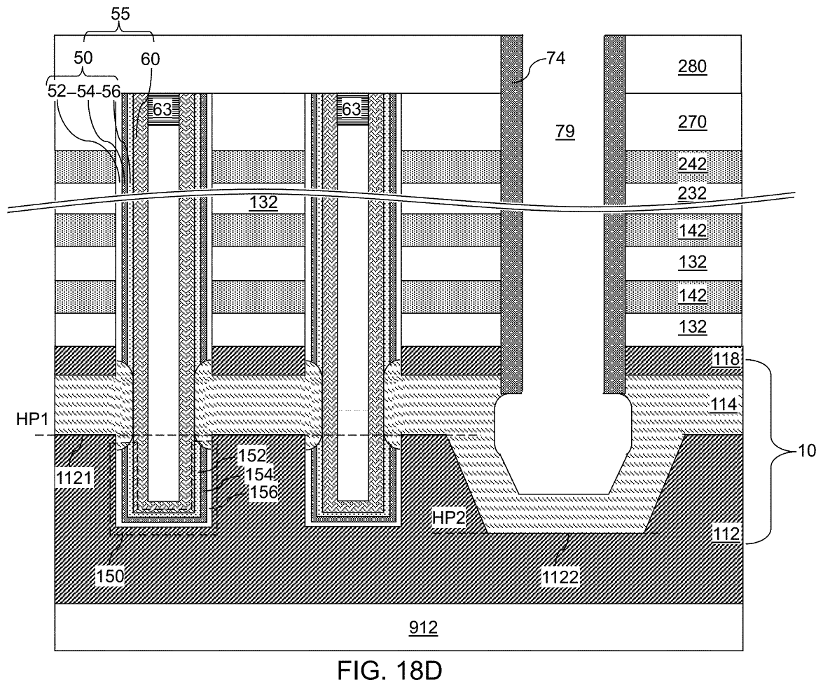

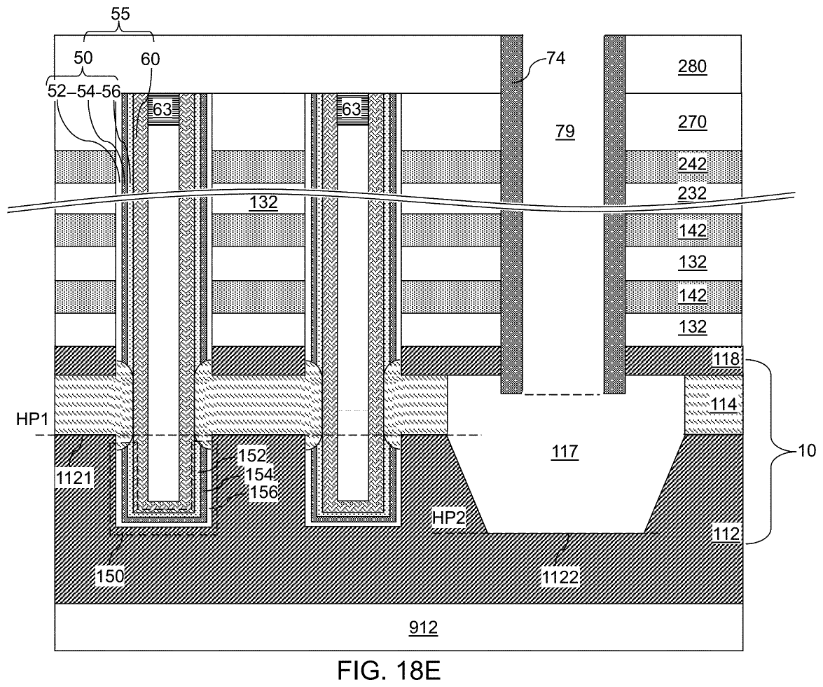

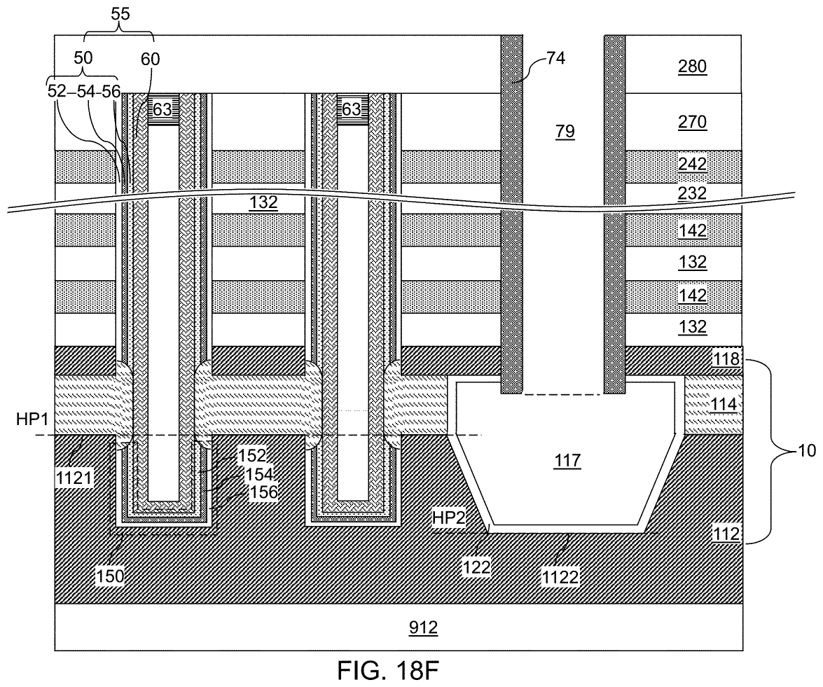

Referring to FIGS. 17 and 18A, a backside trench spacer 74 may be formed on sidewalls of each backside trench 79. For example, a conformal spacer material layer may be deposited in the backside trenches 79 and over the first contact level dielectric layer 280, and may be anisotropically etched to form the backside trench spacers 74. The backside trench spacers 74 include a material that is different from the material of the sacrificial source-level material layer 104. For example, the backside trench spacers 74 may include silicon nitride.

Referring to FIG. 18B, an etchant that etches the material of the sacrificial source-level material layer 104 selective to the materials of the first alternating stack (132, 142), the second alternating stack (232, 242), the first and second insulating cap layers (170, 270), the first contact level dielectric layer 280, the upper etch stop dielectric liner 107, and the lower etch stop dielectric liner 103 may be introduced into the backside trenches in an isotropic etch process. For example, if the sacrificial source-level material layer 104 includes undoped amorphous silicon or an undoped amorphous silicon-germanium alloy, the backside trench spacers 74 include silicon nitride, and the upper and lower etch stop liners (107, 103) include silicon oxide, a wet etch process using hot trimethyl-2 hydroxyethyl ammonium hydroxide (“hot TMY”) or tetramethyl ammonium hydroxide (TMAH) may be used to remove the sacrificial source-level material layer 104 selective to the backside trench spacers 74 and the upper and lower etch stop liners (107, 103). A source cavity 109 may be formed in the volume from which the sacrificial source-level material layer 104 is removed.

Wet etch chemicals such as hot TMY and TMAH are selective to doped semiconductor materials such as the doped semiconductor materials of the upper source layer 118 and the lower source layer 112. Thus, use of selective wet etch chemicals such as hot TMY and TMAH for the wet etch process that forms the source cavity 109 provides a large process window against etch depth variation during formation of the backside trenches 79. Specifically, even if sidewalls of the upper source layer 118 are physically exposed or even if a surface of the lower source layer 112 is physically exposed upon formation of the source cavity 109 and/or the backside trench spacers 74, collateral etching of the upper source layer 118 and/or the lower source layer 112 is minimal, and the structural change to the exemplary structure caused by accidental physical exposure of the surfaces of the upper source layer 118 and/or the lower source layer 112 during manufacturing steps do not result in device failures. Each of the memory opening fill structures 58 is physically exposed to the source cavity 109. Specifically, each of the memory opening fill structures 58 includes a sidewall and that are physically exposed to the source cavity 109.

Referring to FIG. 18C, a sequence of isotropic etchants, such as wet etchants, may be applied to the physically exposed portions of the memory films 50 to sequentially etch the various component layers of the memory films 50 from outside to inside, and to physically expose cylindrical surfaces of the vertical semiconductor channels 60 at the level of the source cavity 109. The upper and lower etch stop liners (107, 103) may be collaterally etched during removal of the portions of the memory films 50 located at the level of the source cavity 109. The lower etch stop dielectric liner 103, the upper etch stop dielectric liner 107, and portions of the memory films 50 physically exposed to the source cavity 109 are removed such that sidewalls of the vertical semiconductor channels 60 are physically exposed. The source cavity 109 may be expanded in volume by removal of the portions of the memory films 50 at the level of the source cavity 109 and the upper and lower etch stop liners (107, 103). A top surface of the lower source layer 112 and a bottom surface of the upper source layer 118 may be physically exposed to the source cavity 109. The source cavity 109 may be expanded by isotropically etching the sacrificial source-level material layer 104 and a bottom portion of each of the memory films 50 selective to at least one source-level semiconductor layer (such as the lower source layer 112 and the upper source layer 118) and the vertical semiconductor channels 60. Surfaces of the lower source layer 112 that are physically exposed to the source cavity 109 include a first horizontal surface 1121 that is a topmost surface of the lower source layer 112 located within a first horizontal plane HP1, and second horizontal surfaces 1122 that are recessed surfaces of the lower source layer 112 that underlie the backside trenches 79 and are located within a second horizontal plane HP2.

Each remaining portion of the memory films 50 that remain underneath the first horizontal plane HP1 constitutes a dielectric cap structure 150. The dielectric cap structures 150 may be formed within the lower source layer 112 below the first horizontal plane HP1, and surround and contact a respective one of the vertical semiconductor channels 60. In one embodiment, each of the memory films 50 comprises a first layer stack including a charge storage layer 54 and a tunneling dielectric 56, and each of the dielectric cap structures 150 comprises a second layer stack including a dielectric material layer 154 having a same thickness as, and a same material composition as, the charge storage layer 54 and another dielectric material layer 156 having a same thickness as, and a same material composition as, the tunneling dielectric 56. In one embodiment, the first layer stack may include a blocking dielectric 52, and the second layer stack may include yet another dielectric layer 152 having a same thickness as, and a same material composition as, the blocking dielectric 52.

Referring to FIG. 18D, a semiconductor material having a doping of the second conductivity type may be deposited on the physically exposed semiconductor surfaces around the source cavity 109. The physically exposed semiconductor surfaces include bottom portions of outer sidewalls of the vertical semiconductor channels 60 and a horizontal surface of the at least one source-level semiconductor layer (such as a bottom surface of the upper source layer 118 and/or a top surface of the lower source layer 112). For example, the physically exposed semiconductor surfaces may include the bottom portions of outer sidewalls of the vertical semiconductor channels 60, the physically exposed surfaces of the lower source layer 112, and the bottom surface of the upper source layer 118.

In one embodiment, the doped semiconductor material of the second conductivity type may be deposited on the physically exposed semiconductor surfaces around the source cavity 109 by a selective semiconductor deposition process. A semiconductor precursor gas, an etchant, and a dopant gas may be flowed concurrently into a process chamber including the exemplary structure during the selective semiconductor deposition process. For example, the semiconductor precursor gas may include silane, disilane, or dichlorosilane, the etchant gas may include gaseous hydrogen chloride, and the dopant gas may include a hydride of a dopant atom such as phosphine, arsine, stibine, or diborane. In such an embodiment, the selective semiconductor deposition process grows a doped semiconductor material having a doping of the second conductivity type from physically exposed semiconductor surfaces around the source cavity 109. The deposited doped semiconductor material forms a source contact layer 114, which may contact sidewalls of the vertical semiconductor channels 60. The atomic concentration of the dopants of the second conductivity type in the deposited semiconductor material may be in a range from 1.0×10²⁰/cm³ to 2.033 10²¹/cm³, such as from 2.0×10²⁰/cm³ to 8.0×10²⁰/cm³. The source contact layer 114 as initially formed may consist essentially of semiconductor atoms and dopant atoms of the second conductivity type. Alternatively, at least one non-selective doped semiconductor material deposition process may be used to form the source contact layer 114. Optionally, one or more etch back processes may be used in combination with a plurality of selective or non-selective deposition processes to provide a seamless and/or voidless source contact layer 114. The source contact layer 114 is formed in the source cavity 109 directly on the sidewalls of the vertical semiconductor channels 60.

The duration of the selective semiconductor deposition process may be selected such that the source cavity 109 may be filled with the source contact layer 114 except volumes that overlie the recess trenches in the lower source layer 112. The source contact layer 114 may contact bottom end portions of outer sidewalls of the backside trench spacers 74. In one embodiment, the source contact layer 114 may be formed by selectively depositing a doped semiconductor material having a doping of the second conductivity type from semiconductor surfaces around the source cavity 109. In one embodiment, the doped semiconductor material may include doped polysilicon.

Thus, the sacrificial source-level material layer 104 may be replaced with the source contact layer 114. The layer stack including the lower source layer 112, the source contact layer 114, and the upper source layer 118 constitutes source-level material layers 10. In one embodiment, the vertical semiconductor channels 60 comprise a semiconductor material having a doping of a first conductivity type, and the source contact layer 114 may be formed by conformal deposition of a doped semiconductor material having a doping of the second conductivity type within the source cavity 109. In this case, a cylindrical p-n junction may be formed at each interface between the source contact layer 114 and the vertical semiconductor channels 60.

Referring to FIG. 18E, the doped semiconductor material of the source contact layer 114 may be isotropically recessed underneath each backside trench 79 by an isotropic etch process. A void 117 may be formed underneath each backside trench 79. The source contact layer 114 may include the remaining portions of the doped semiconductor material of the source contact layer 114 as provided at the processing steps of FIG. 18D. In one embodiment, the second horizontal surfaces 1122 and vertical or tapered sidewalls of the recess trenches of the lower source layer 112 may be physically exposed to a void 117 underlying the backside trenches 79.

Referring to FIG. 18F, a dielectric liner 122 may be formed around each void 117, for example, by thermal oxidation of the semiconductor materials of physically exposed surface portions of the source-level material layers 10 around each void 117. Each dielectric liner 112 contacts a sidewall of the source contact layer 114, and contacts a sidewall of the lower source layer that connects the first horizontal surface to the second horizontal surface. Each dielectric liner 112 may have a thickness in a range from 2 nm to 10 nm, although lesser and greater thicknesses may also be used. A topmost surface of each dielectric liner 122 may have an annular shape, and may contact a bottom surface of the upper source layer 118.

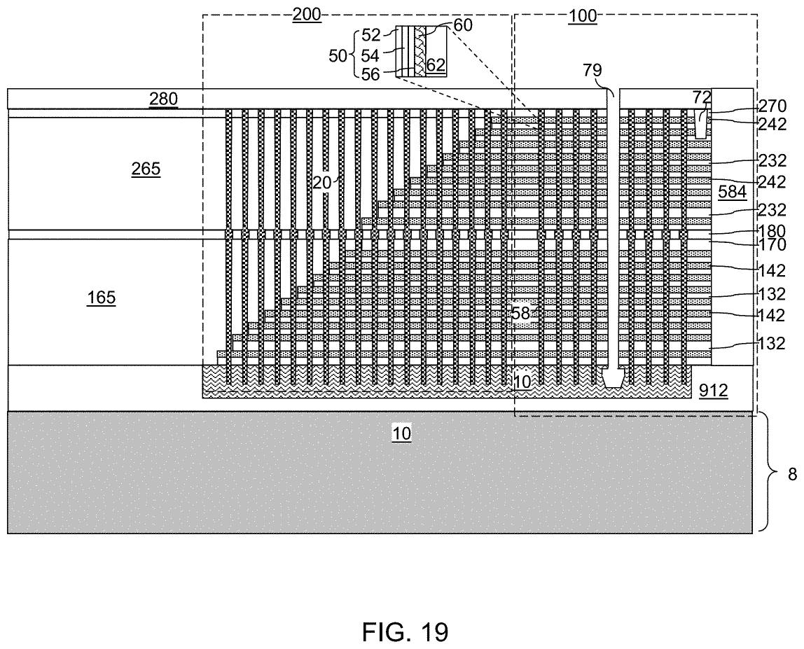

Referring to FIG. 19, the backside trench spacers 74 may be removed selective to the insulating layers (132, 232), the first and second insulating cap layers (170, 270), the first contact level dielectric layer 280, and the dielectric liners 122 using an isotropic etch process. For example, if the backside trench spacers 74 include silicon nitride, a wet etch process using hot phosphoric acid may be performed to remove the backside trench spacers 74. In one embodiment, the isotropic etch process that removes the backside trench spacers 74 may be combined with a subsequent isotropic etch process that etches the sacrificial material layers (142, 242) selective to the insulating layers (132, 232), the first and second insulating cap layers (170, 270), the first contact level dielectric layer 280, and the dielectric liners 122.

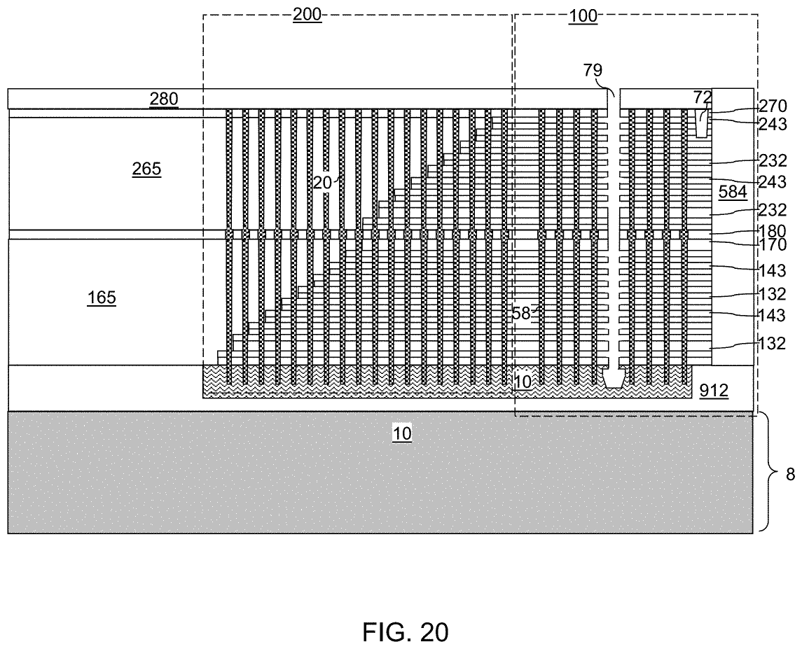

Referring to FIG. 20, the sacrificial material layers (142, 242) may be removed selective to the insulating layers (132, 232), the first and second insulating cap layers (170, 270), the first contact level dielectric layer 280, and the source contact layer 114, the dielectric semiconductor oxide plates 122, and the annular dielectric semiconductor oxide spacers 124. For example, an etchant that selectively etches the materials of the sacrificial material layers (142, 242) with respect to the materials of the insulating layers (132, 232), the first and second insulating cap layers (170, 270), the retro-stepped dielectric material portions (165, 265), and the material of the outermost layer of the memory films 50 may be introduced into the backside trenches 79, for example, using an isotropic etch process. For example, the sacrificial material layers (142, 242) may include silicon nitride, the materials of the insulating layers (132, 232), the first and second insulating cap layers (170, 270), the retro-stepped dielectric material portions (165, 265), and the outermost layer of the memory films 50 may include silicon oxide materials.

The isotropic etch process may be a wet etch process using a wet etch solution, or may be a gas phase (dry) etch process in which the etchant is introduced in a vapor phase into the backside trench 79. For example, if the sacrificial material layers (142, 242) include silicon nitride, the etch process may be a wet etch process in which the exemplary structure is immersed within a wet etch tank including phosphoric acid, which etches silicon nitride selective to silicon oxide, silicon, and various other materials used in the art.

Backside recesses (143, 243) may be formed in volumes from which the sacrificial material layers (142, 242) are removed. The backside recesses (143, 243) include first backside recesses 143 that may be formed in volumes from which the first sacrificial material layers 142 are removed and second backside recesses 243 that may be formed in volumes from which the second sacrificial material layers 242 are removed. Each of the backside recesses (143, 243) may be a laterally extending cavity having a lateral dimension that is greater than the vertical extent of the cavity. In other words, the lateral dimension of each of the backside recesses (143, 243) may be greater than the height of the respective backside recess (143, 243). A plurality of backside recesses (143, 243) may be formed in the volumes from which the material of the sacrificial material layers (142, 242) is removed. Each of the backside recesses (143, 243) may extend substantially parallel to the top surface of the substrate semiconductor layer 8. A backside recess (143, 243) may be vertically bounded by a top surface of an underlying insulating layer (132, 232) and a bottom surface of an overlying insulating layer (132, 232). In one embodiment, each of the backside recesses (143, 243) may have a uniform height throughout.

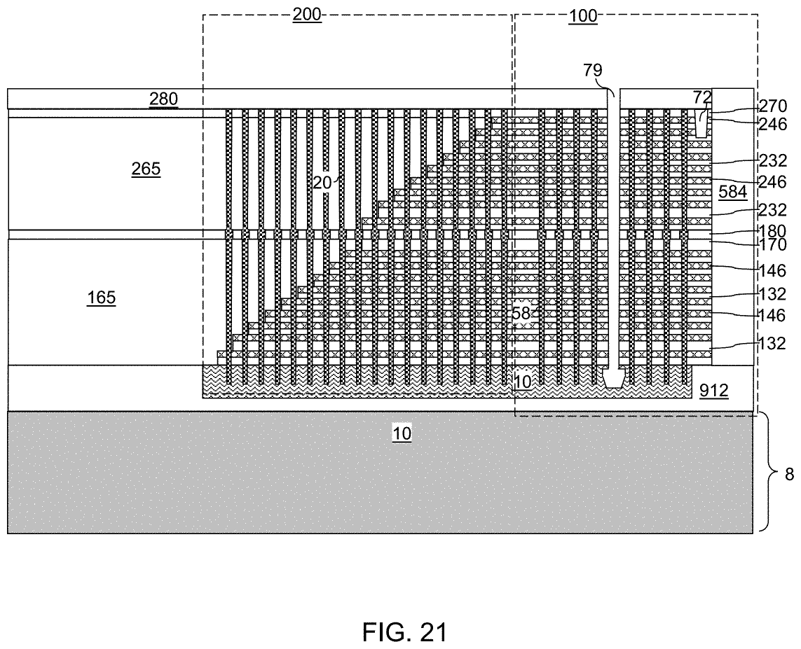

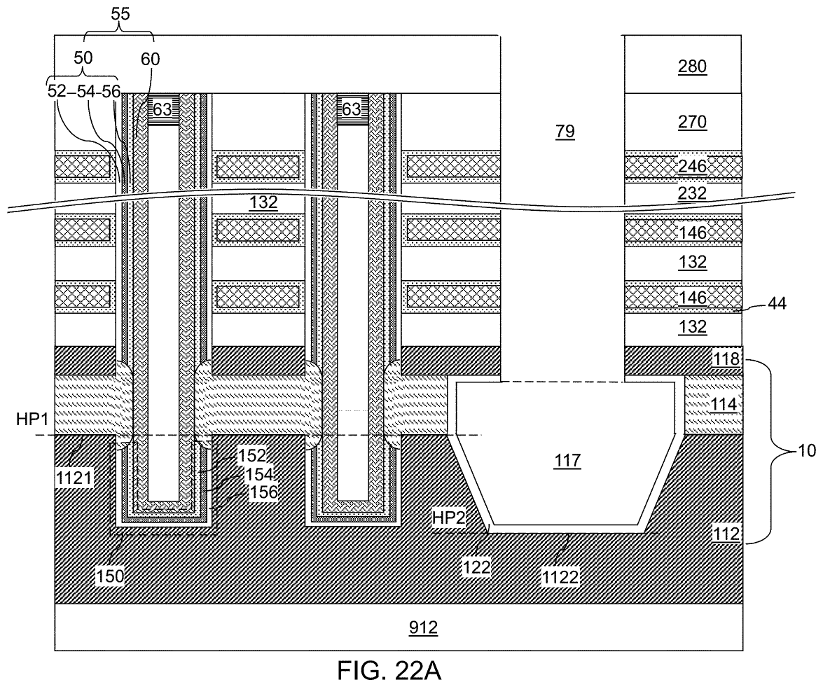

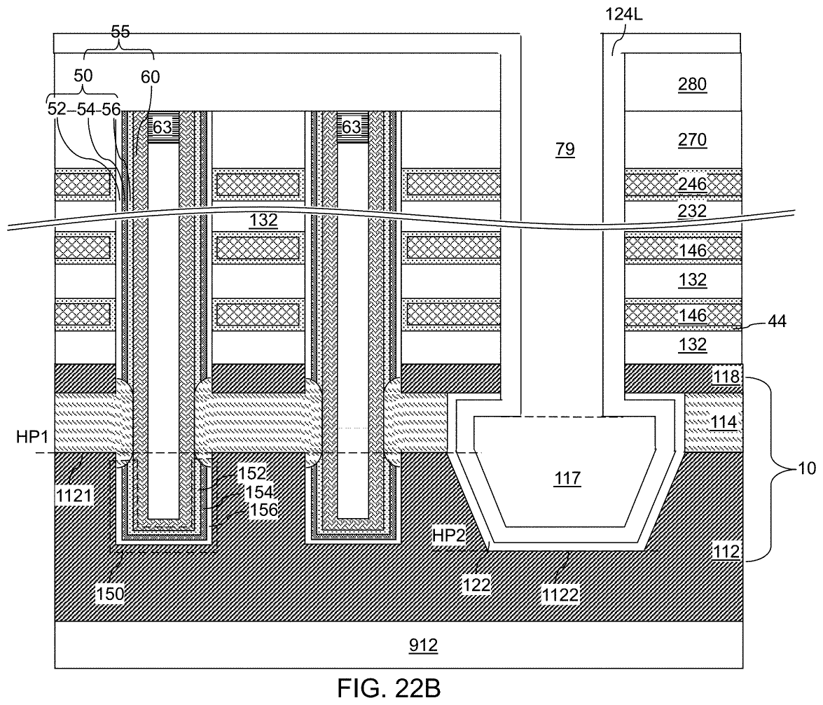

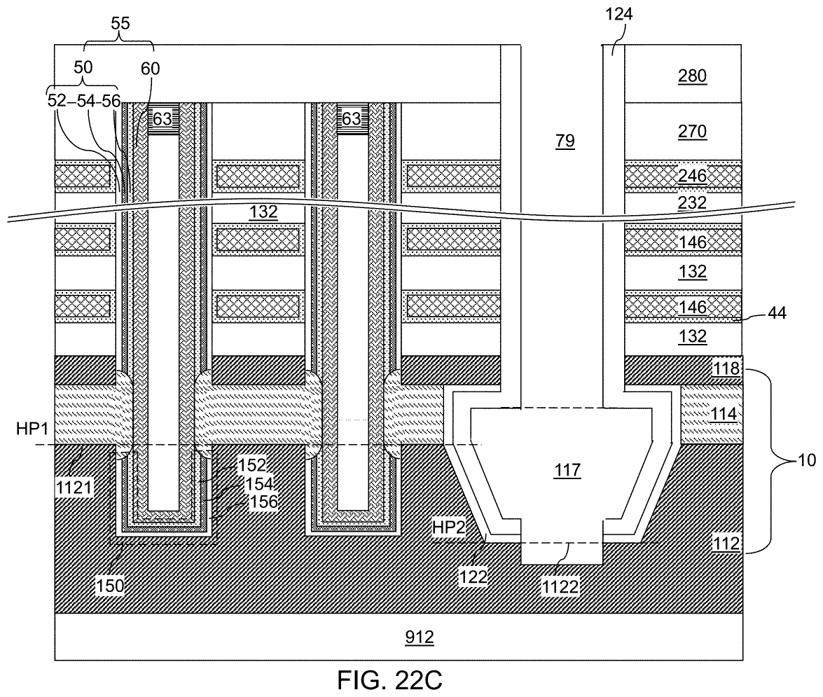

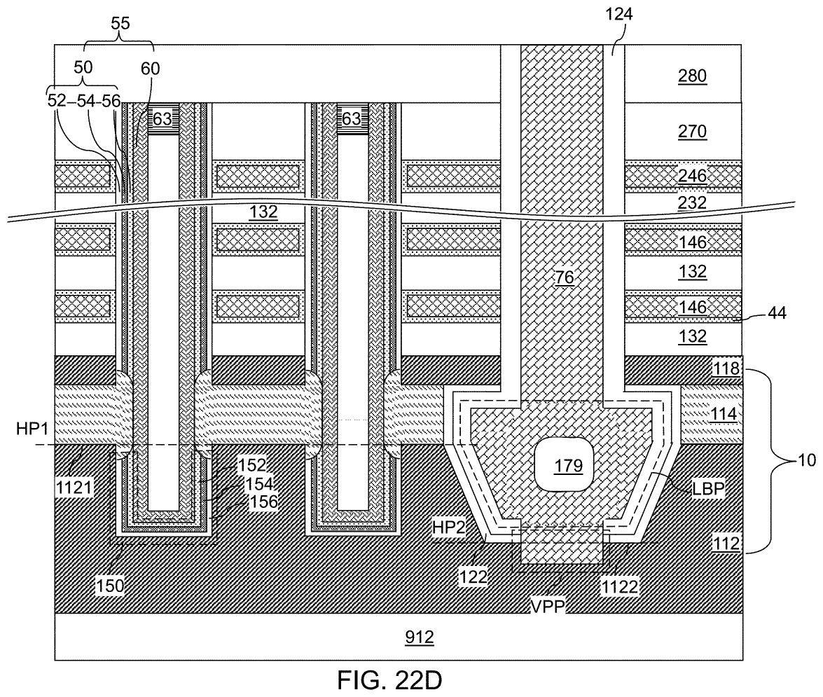

Referring to FIGS. 21 and 22A, a backside blocking dielectric layer 44 may be optionally deposited in the backside recesses (143, 243) and the backside trenches 79 and over the first contact level dielectric layer 280. The backside blocking dielectric layer 44 may include a dielectric material such as a dielectric metal oxide, silicon oxide, or a combination thereof. For example, the backside blocking dielectric layer 44 may include aluminum oxide. The backside blocking dielectric layer 44 may be formed by a conformal deposition process such as atomic layer deposition or chemical vapor deposition. The thickness of the backside blocking dielectric layer 44 may be in a range from 1 nm to 20 nm, such as from 2 nm to 10 nm, although lesser and greater thicknesses may also be used.

At least one conductive material may be deposited in the plurality of backside recesses (143, 243), on the sidewalls of the backside trenches 79, and over the first contact level dielectric layer 280. The at least one conductive material may be deposited by a conformal deposition method, which may be, for example, chemical vapor deposition (CVD), atomic layer deposition (ALD), electroless plating, electroplating, or a combination thereof. The at least one conductive material may include an elemental metal, an intermetallic alloy of at least two elemental metals, a conductive nitride of at least one elemental metal, a conductive metal oxide, a conductive doped semiconductor material, a conductive metal-semiconductor alloy such as a metal silicide, alloys thereof, and combinations or stacks thereof.

In one embodiment, the at least one conductive material may include at least one metallic material, i.e., an electrically conductive material that includes at least one metallic element. Non-limiting exemplary metallic materials that may be deposited in the backside recesses (143, 243) include tungsten, tungsten nitride, titanium, titanium nitride, tantalum, tantalum nitride, cobalt, and ruthenium. For example, the at least one conductive material may include a conductive metallic nitride liner that includes a conductive metallic nitride material such as TiN, TaN, WN, or a combination thereof, and a conductive fill material such as W, Co, Ru, Mo, Cu, or combinations thereof. In one embodiment, the at least one conductive material for filling the backside recesses (143, 243) may be a combination of titanium nitride layer and a tungsten fill material.

Electrically conductive layers (146, 246) may be formed in the backside recesses (143, 243) by deposition of the at least one conductive material. A plurality of first electrically conductive layers 146 may be formed in the plurality of first backside recesses 143, a plurality of second electrically conductive layers 246 may be formed in the plurality of second backside recesses 243, and a continuous metallic material layer (not shown) may be formed on the sidewalls of each backside trench 79 and over the first contact level dielectric layer 280. Each of the first electrically conductive layers 146 and the second electrically conductive layers 246 may include a respective conductive metallic nitride liner and a respective conductive fill material. Thus, the first and second sacrificial material layers (142, 242) may be replaced with the first and second electrically conductive layers (146, 246), respectively. Specifically, each first sacrificial material layer 142 may be replaced with an optional portion of the backside blocking dielectric layer and a first electrically conductive layer 146, and each second sacrificial material layer 242 may be replaced with an optional portion of the backside blocking dielectric layer and a second electrically conductive layer 246. A backside cavity is present in the portion of each backside trench 79 that is not filled with the continuous metallic material layer.

Residual conductive material may be removed from inside the backside trenches 79. Specifically, the deposited metallic material of the continuous metallic material layer may be etched back from the sidewalls of each backside trench 79 and from above the first contact level dielectric layer 280, from within the backside trenches 79, and from within the voids 117, for example, by an anisotropic etch process and/or an isotropic etch process. Each remaining portion of the deposited metallic material in the first backside recesses constitutes a first electrically conductive layer 146. Each remaining portion of the deposited metallic material in the second backside recesses constitutes a second electrically conductive layer 246. Sidewalls of the first electrically conductive material layers 146 and the second electrically conductive layers may be physically exposed to a respective backside trench 79.

Each electrically conductive layer (146, 246) may be a conductive sheet including openings therein. A first subset of the openings through each electrically conductive layer (146, 246) may be filled with memory opening fill structures 58. A second subset of the openings through each electrically conductive layer (146, 246) may be filled with the support pillar structures 20. Each electrically conductive layer (146, 246) may have a lesser area than any underlying electrically conductive layer (146, 246) because of the first and second stepped surfaces. Each electrically conductive layer (146, 246) may have a greater area than any overlying electrically conductive layer (146, 246) because of the first and second stepped surfaces.

In some embodiment, drain-select-level isolation structures 72 may be provided at topmost levels of the second electrically conductive layers 246. A subset of the second electrically conductive layers 246 located at the levels of the drain-select-level isolation structures 72 constitutes drain select gate electrodes. A subset of the electrically conductive layer (146, 246) located underneath the drain select gate electrodes may function as combinations of a control gate and a word line located at the same level. The control gate electrodes within each electrically conductive layer (146, 246) are the control gate electrodes for a vertical memory device including the memory stack structure 55.

Each of the memory stack structures 55 may comprise a vertical stack of memory elements located at each level of the electrically conductive layers (146, 246). A subset of the electrically conductive layers (146, 246) may comprise word lines for the memory elements. The semiconductor devices in the underlying peripheral device region 400 may comprise word line switch devices configured to control a bias voltage to respective word lines. The memory-level assembly is located over the substrate semiconductor layer 8. The memory-level assembly includes at least one alternating stack (132, 146, 232, 246) and memory stack structures 55 vertically extending through the at least one alternating stack (132, 146, 232, 246).

Referring to FIGS. 22A and 22B, a dielectric material layer 124L may be conformally deposited in the backside trenches 79, in the voids 117, and over the first contact level dielectric layer 280 by a conformal deposition process. The dielectric material layer 124L may include, for example, silicon oxide. The thickness of the dielectric material may be in a range from 10 nm to 50 nm, although lesser and greater thicknesses may also be used.

Referring to FIG. 22C, an anisotropic etch process may be performed to remove horizontal portions of the dielectric material layer 124L. Horizontal portions of the dielectric material layer 124L may be removed from above the first contact level dielectric layer 280 and at the bottom of each void 117, i.e., at the bottom of each recess trench. Further, a center portion of a dielectric liner 122 may be removed from underneath each backside trench 79 to physically expose a surface of the lower source layer 112. In one embodiment, a physically exposed surface of the lower source layer 112 may be vertically recessed relative to a bottommost surface of the dielectric liner 122. Each remaining portion of the dielectric material layer 124L located at peripheral portion of a backside trench 79 and an underlying void 117 constitutes an insulating spacer 124.

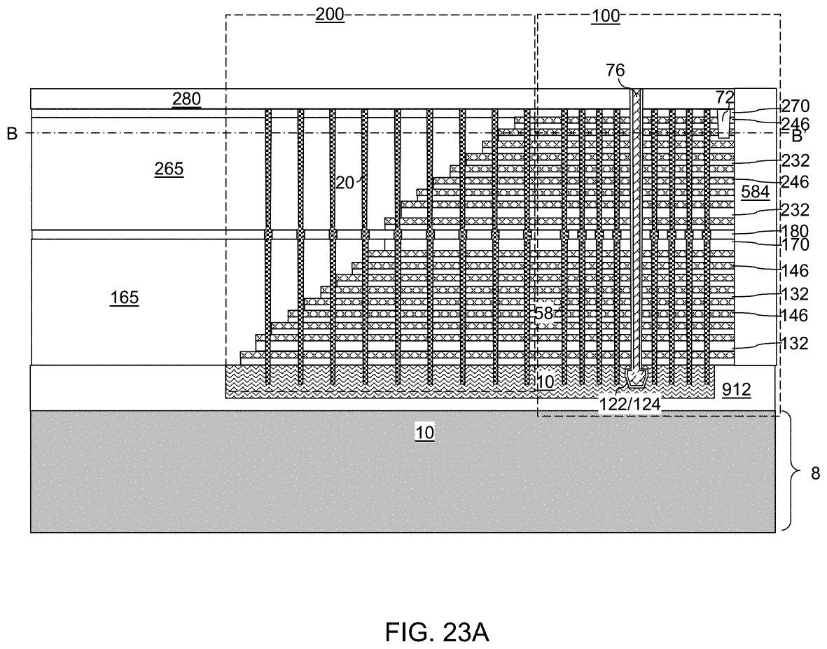

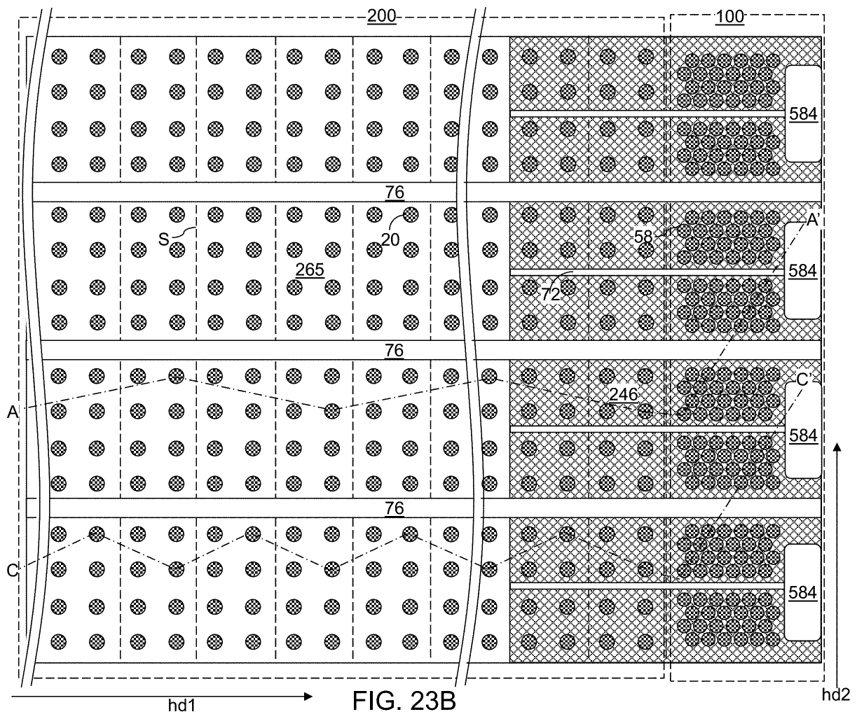

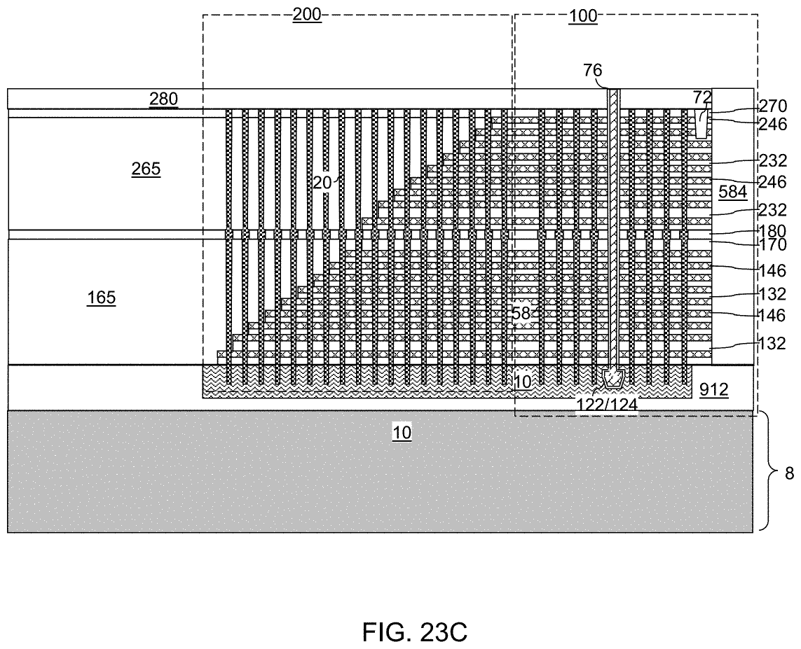

Referring to FIGS. 22D and 23A-23C, at least one conductive material may be deposited in unfilled volumes of the backside trenches 79 and the voids 117. Excess portions of the at least one conductive material may be removed from above the top surface of the first contact level dielectric layer 280 by a planarization process. The planarization process may use a recess etch process or a chemical mechanical planarization process. Each remaining portion of the at least one conductive material filling a backside trench 79 and an underlying void 117 constitutes a backside contact via structure 76. Each backside contact via structure 76 may be formed directly on an inner sidewall of a respective insulating spacer 124 and directly on a surface of the lower source layer 112. A backside contact via structure may form a cavity 179 within a laterally bulging portion LBP, and may include a vertically protruding portion VPP that extends downward through the dielectric liner 122 to contact a surface of the lower source layer 112.

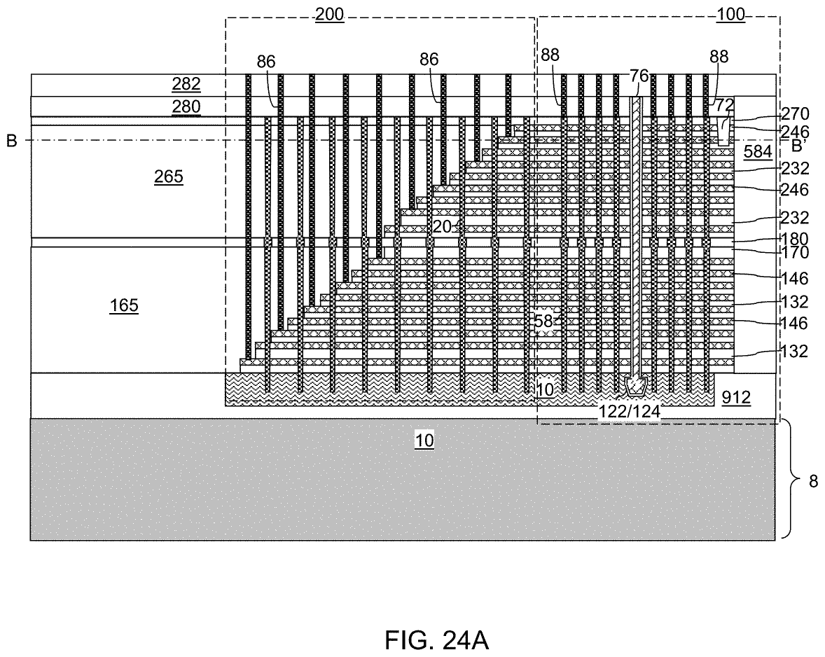

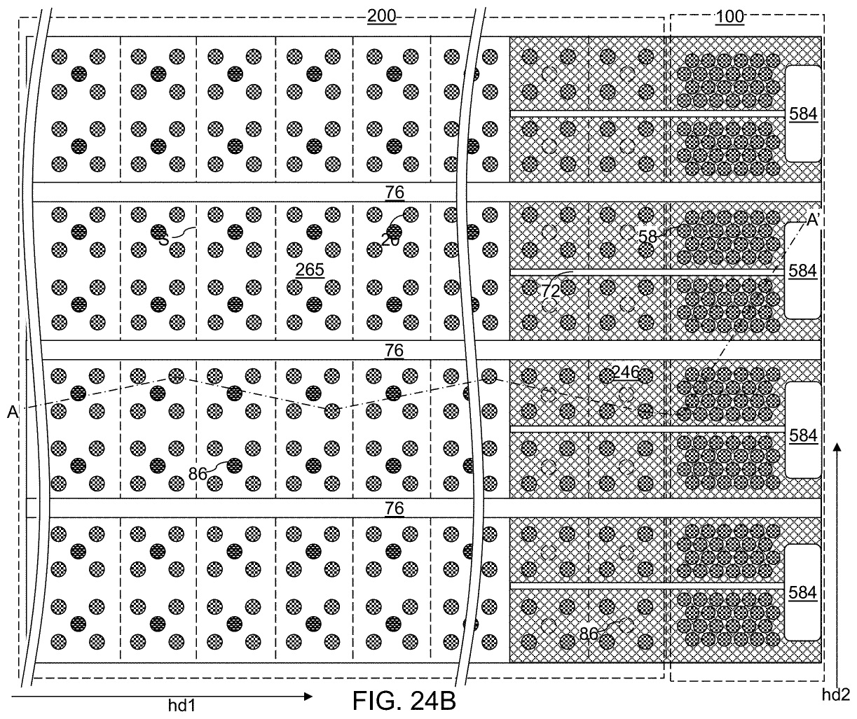

Referring to FIGS. 24A and 24B, a second contact level dielectric layer 282 may be formed over the first contact level dielectric layer 280. The second contact level dielectric layer 282 includes a dielectric material such as silicon oxide, and may have a thickness in a range from 100 nm to 600 nm, although lesser and greater thicknesses may also be used.

A photoresist layer (not shown) may be applied over the second contact level dielectric layer 282, and may be lithographically patterned to form various contact via openings. For example, openings for forming drain contact via structures may be formed in the memory array region 100, and openings for forming staircase region contact via structures may be formed in the staircase region 200. An anisotropic etch process is performed to transfer the pattern in the photoresist layer through the second and first contact level dielectric layers (282, 280) and underlying dielectric material portions. The drain regions 63 and the electrically conductive layers (146, 246) may be used as etch stop structures. Drain contact via cavities may be formed over each drain region 63, and staircase-region contact via cavities may be formed over each electrically conductive layer (146. 246) at the stepped surfaces underlying the first and second retro-stepped dielectric material portions (165, 265). The photoresist layer may be subsequently removed, for example, by ashing.

Drain contact via structures 88 may be formed in the drain contact via cavities and on a top surface of a respective one of the drain regions 63. Staircase-region contact via structures 86 may be formed in the staircase-region contact via cavities and on a top surface of a respective one of the electrically conductive layers (146, 246). The staircase-region contact via structures 86 may include drain select level contact via structures that contact a subset of the second electrically conductive layers 246 that function as drain select level gate electrodes. Further, the staircase-region contact via structures 86 may include word line contact via structures that contact electrically conductive layers (146, 246) that underlie the drain select level gate electrodes and function as word lines for the memory stack structures 55.

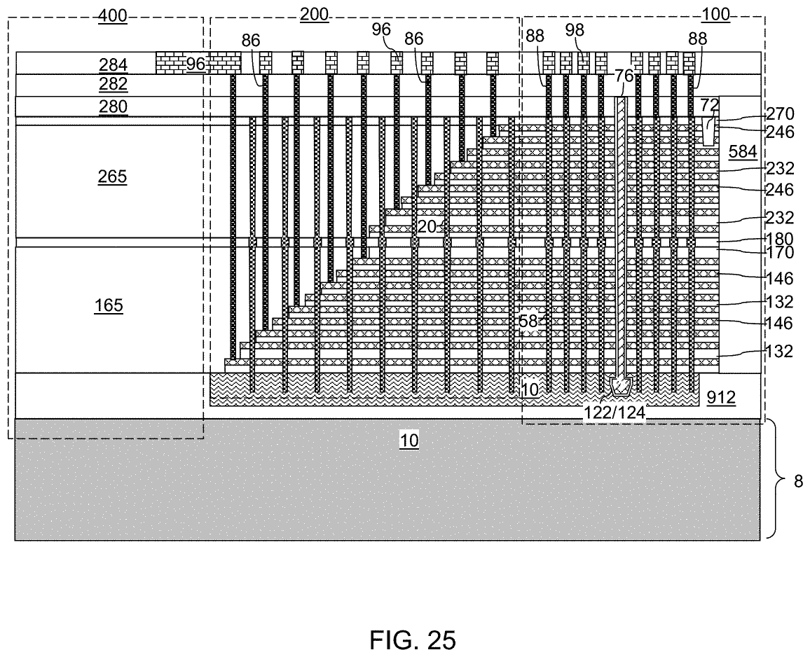

Referring to FIG. 25, at least one additional dielectric layer may be formed over the contact level dielectric layers (280, 282), and additional metal interconnect structures (herein referred to as upper-level metal interconnect structures) may be formed in the at least one additional dielectric layer. For example, the at least one additional dielectric layer may include a line-level dielectric layer 284 that is formed over the contact level dielectric layers (280, 282). The upper-level metal interconnect structures may include bit lines 98 contacting a respective one of the drain contact via structures 88, and interconnection line structures 96 contacting, and/or electrically connected to, at least one of the staircase-region contact via structures 86.

Referring to all drawings and according to various embodiments of the present disclosure, a three-dimensional memory device may be provided, which comprises: source-level material layers 10 located on a substrate 8, wherein the source-level material layers 10 comprise, from bottom to top, a lower source layer 112, a source contact layer 114, and an upper source layer 118, wherein the lower source layer 112 comprises a first horizontal surface 1121 located within a first horizontal plane HP1 and contacting a bottom surface of the source contact layer 114 and a second horizontal surface 1122 located within a second horizontal plane HP2 located below the first horizontal plane HP1; an alternating stack of insulating layers (132, 232) and electrically conductive layers (146, 246) located over the source-level material layers 10; memory stack structures 55 vertically extending through the alternating stack {(132, 146), (232, 246)} and comprising a respective memory film 50 and a respective vertical semiconductor channel 60 having a sidewall that contacts the source contact layer 114; and a backside contact via structure 76 extending through each layer within the alternating stack {(132, 146), (232, 246)}, the upper source layer 118, the source contact layer 114, and an opening through the second horizontal surface 1122 and contacting the lower source layer 112.

In one embodiment, the three-dimensional memory device comprises a recess trench 209 in which the lower source layer 112 may be vertically recessed relative to the first horizontal plane HP1, wherein the recess trench 209 comprises sidewalls that adjoin a respective portion of the second horizontal surface 1122 to the first horizontal surface 1121. In one embodiment, sidewalls of the backside contact via structure 76 that vertically extend through the alternating stack {(132, 146), (232, 246)} are located entirely within an area defined by an outer periphery of the second horizontal surface 1122 as illustrated in FIGS. 22A-22D.

In one embodiment, the backside contact via structure 76 comprises a laterally bulging portion LBP at a level of the source contact layer 114 as illustrated in FIG. 22D; and a lateral extent of the laterally bulging portion LBP may be greater than a lateral extent of a portion of the backside contact via structure 76 located at a level of a bottommost layer of the insulating layers (132, 232).

In one embodiment, the three-dimensional memory device comprises an insulating spacer 124 that laterally surrounds the backside contact via structure 76 and vertically extends through each layer within the alternating stack {(132, 146), (232, 246)}, the upper source layer 118, and the source contact layer 114, and below the first horizontal plane HP1.

In one embodiment, the three-dimensional memory device comprises a dielectric liner 112 laterally surrounding a lower portion of the insulating spacer 124, contacting a sidewall of the source contact layer 114, and contacting a sidewall of the lower source layer 112 that connects the first horizontal surface 1121 to the second horizontal surface 1122 as illustrated in FIGS. 22A-22D. In one embodiment, a topmost surface of the dielectric liner 122 has an annular shape and contacts a bottom surface of the upper source layer 118. In one embodiment, the backside contact via structure 76 comprises a vertically protruding portion VPP having a lateral extent that is less than the lateral extent of the laterally bulging portion LBP, and vertically extending below the second horizontal plane HP2 into the lower source layer 112.

In one embodiment, the vertical semiconductor channels 60 extend below the first horizontal plane HP1; and dielectric cap structures 150 may be formed within the lower source layer 112 below the first horizontal plane HP1, and surround and contact a respective one of the vertical semiconductor channels 60.

In one embodiment, each of the memory films 50 comprises a first layer stack including a charge storage layer 54 and a tunneling dielectric 56; and each of the dielectric cap structures 150 comprises a second layer stack including a dielectric material layer 154 having a same thickness as, and a same material composition as, the charge storage layer 54 and another dielectric material layer 156 having a same thickness as, and a same material composition as, the tunneling dielectric 56.

In one embodiment, the vertical semiconductor channels 60 have a doping of a first conductivity type; and the source contact layer 114 comprises a semiconductor material having a doping of a second conductivity type that is the opposite of the first conductivity type. In one embodiment, the lower source layer 112 comprises a first semiconductor material having a doping of the second conductivity type; and the upper source layer 118 comprises a second semiconductor material having a doping of the second conductivity type.

In one embodiment, each of the memory films 50 comprises an annular bottom surface that contacts the source contact layer 114; and a bottom periphery of an outer sidewall of each of the memory films 50 contacts a vertical sidewall of a respective opening through the upper source layer 118. In one embodiment, the annular bottom surface of each memory film 50 may be a concave annular surface.

In one embodiment, the three-dimensional memory device comprises a monolithic three-dimensional NAND memory device, the electrically conductive strips (146, 246) comprise, or are electrically connected to, a respective word line of the monolithic three-dimensional NAND memory device, the substrate 8 comprises a silicon substrate, the monolithic three-dimensional NAND memory device comprises an array of monolithic three-dimensional NAND strings over the silicon substrate, and at least one memory cell in a first device level of the array of monolithic three-dimensional NAND strings is located over another memory cell in a second device level of the array of monolithic three-dimensional NAND strings. The silicon substrate may contain an integrated circuit comprising a driver circuit for the memory device located thereon, the electrically conductive strips (146, 246) comprise a plurality of control gate electrodes having a strip shape extending substantially parallel to the top surface of the substrate 8, the plurality of control gate electrodes comprise at least a first control gate electrode located in the first device level and a second control gate electrode located in the second device level. The array of monolithic three-dimensional NAND strings comprises a plurality of semiconductor channels 60, wherein at least one end portion of each of the plurality of semiconductor channels 60 extends substantially perpendicular to a top surface of the substrate 8, and one of the plurality of semiconductor channels including the vertical semiconductor channel 60. The array of monolithic three-dimensional NAND strings comprises a plurality of charge storage elements (comprising portions of the memory films 50), each charge storage element located adjacent to a respective one of the plurality of semiconductor channels 60.

Although the foregoing refers to particular embodiments, it will be understood that the disclosure is not so limited. It will occur to those of ordinary skill in the art that various modifications may be made to the disclosed embodiments and that such modifications are intended to be within the scope of the disclosure. Compatibility is presumed among all embodiments that are not alternatives of one another. The word “comprise” or “include” contemplates all embodiments in which the word “consist essentially of” or the word “consists of” replaces the word “comprise” or “include,” unless explicitly stated otherwise. Where an embodiment using a particular structure and/or configuration is illustrated in the present disclosure, it is understood that the present disclosure may be practiced with any other compatible structures and/or configurations that are functionally equivalent provided that such substitutions are not explicitly forbidden or otherwise known to be impossible to one of ordinary skill in the art. All of the publications, patent applications and patents cited herein are incorporated herein by reference in their entirety.

What is claimed is:

1. A three-dimensional memory device, comprising:
source-level material layers located over a substrate, wherein the source-level material layers comprise, from bottom to top:
a lower source layer;
a source contact layer; and
an upper source layer, wherein the lower source layer comprises a first horizontal surface located within a first horizontal plane and contacting a bottom surface of the source contact layer and a second horizontal surface located within a second horizontal plane located below the first horizontal plane;
an alternating stack of insulating layers and electrically conductive layers located over the source-level material layers;
memory stack structures vertically extending through the alternating stack and comprising a respective memory film and a respective vertical semiconductor channel having a sidewall that contacts the source contact layer; and
a backside contact via structure extending through each layer within the alternating stack, the upper source layer, the source contact layer, and an opening through the second horizontal surface and contacting the lower source layer.

2. The three-dimensional memory device of claim 1, further comprising a recess trench in which the lower source layer is vertically recessed relative to the first horizontal plane, wherein the recess trench comprises sidewalls that adjoin a respective portion of the second horizontal surface to the first horizontal surface.

3. The three-dimensional memory device of claim 2, wherein sidewalls of the backside contact via structure that vertically extend through the alternating stack are located entirely within an area defined by an outer periphery of the second horizontal surface.

4. The three-dimensional memory device of claim 1, wherein:
the backside contact via structure comprises a laterally bulging portion at a level of the source contact layer; and
a lateral extent of the laterally bulging portion is greater than a lateral extent of a portion of the backside contact via structure located at a level of a bottommost layer of the insulating layers.

5. The three-dimensional memory device of claim 4, further comprising an insulating spacer that laterally surrounds the backside contact via structure and vertically extends through each layer within the alternating stack, the upper source layer, and the source contact layer, and below the first horizontal plane.

6. The three-dimensional memory device of claim 5, further comprising a dielectric liner laterally surrounding a lower portion of the insulating spacer, contacting a sidewall of the source contact layer, and contacting a sidewall of the lower source layer that connects the first horizontal surface to the second horizontal surface.

7. The three-dimensional memory device of claim 6, wherein a topmost surface of the dielectric liner has an annular shape and contacts a bottom surface of the upper source layer.

8. The three-dimensional memory device of claim 4, wherein the backside contact via structure comprises a vertically protruding portion having a lateral extent that is less than the lateral extent of the laterally bulging portion, and vertically extending below the second horizontal plane into the lower source layer.

9. The three-dimensional memory device of claim 1, wherein:
the vertical semiconductor channels extend below the first horizontal plane; and
dielectric cap structures are formed within the lower source layer below the first horizontal plane, and surround and contact a respective one of the vertical semiconductor channels.

10. The three-dimensional memory device of claim 9, wherein:
each of the memory films comprises a first layer stack including a charge storage layer and a tunneling dielectric; and
each of the dielectric cap structures comprises a second layer stack including a dielectric material layer having a same thickness as, and a same material composition as, the charge storage layer and another dielectric material layer having a same thickness as, and a same material composition as, the tunneling dielectric.

11. The three-dimensional memory device of claim 1, wherein:
the vertical semiconductor channels have a doping of a first conductivity type; and
the source contact layer comprises a semiconductor material having a doping of a second conductivity type that is the opposite of the first conductivity type.

12. The three-dimensional memory device of claim 11, wherein:
the lower source layer comprises a first semiconductor material having a doping of the second conductivity type; and
the upper source layer comprises a second semiconductor material having a doping of the second conductivity type.

13. The three-dimensional memory device of claim 1, wherein:
each of the memory films comprises an annular bottom surface that contacts the source contact layer; and
a bottom periphery of an outer sidewall of each of the memory films contacts a vertical sidewall of a respective opening through the upper source layer.

14. A method for forming a three-dimensional memory device, comprising:
forming in-process source-level material layers over a substrate, wherein the in-process source-level material layers comprise:
a lower source layer;
a sacrificial source-level material layer; and
an upper source layer, wherein the lower source layer comprises a recess trench in which a recessed surface of the lower source layer is vertically recessed relative to a topmost surface of the lower source layer, and the sacrificial source-level material layer comprises a sacrificial recess trench fill portion that that protrudes downward and fills the recess region;
forming an alternating stack of insulating layers and spacer material layers over the in-process source-level material layers;
forming memory stack structures vertically extending through the alternating stack, wherein each of the memory stack structures comprises a respective memory film and a respective vertical semiconductor channel;
forming a backside trench through the alternating stack such that a bottom surface of the backside trench is formed within an area of the recess trench between a top surface of the sacrificial source-level material layer and the recessed surface of the lower source layer; and
replacing the sacrificial source-level material layer with a source contact layer.

15. The method of claim 14, forming a backside contact via structure in the backside trench after formation of the source contact layer, wherein the backside contact via structure is formed directly on a surface of the lower source layer.

16. The method of claim 15, further comprising:
forming a source cavity by removing the sacrificial source-level material layer;
conformally depositing a doped semiconductor material within the source cavity; and
isotropically recessing the doped semiconductor material from underneath the backside trench, wherein remaining portions of the doped semiconductor material constitute the source contact layer and the lower source layer is physically exposed to a void underlying the backside trench.

17. The method of claim 16, further comprising forming an insulating spacer at peripheral portions of the backside trench and the void, wherein the backside contact via structure is formed on an inner sidewall of the insulating spacer.

18. The method of claim 14, wherein forming the in-process source-level material layers comprise:
forming the lower source layer over the substrate;
forming the recess trench in a top portion of the lower source layer;
forming the sacrificial recess trench fill portion in the recess trench;
forming the planar portion of the sacrificial source-level material layer over the topmost surface of the lower source layer and over the sacrificial recess trench fill portion; and
forming the upper source layer over the planar portion of the sacrificial source-level material layer.

19. The method of claim 18, further comprising:
forming a lower etch stop dielectric liner over the lower source layer prior to formation of the sacrificial recess trench fill portion;
forming an upper etch stop dielectric liner on the sacrificial source-level material layer;
removing the sacrificial source-level material layer selective to the lower etch stop dielectric liner and the upper etch stop dielectric liner to form a source cavity;
removing the lower etch stop dielectric liner, the upper etch stop dielectric liner, and portions of the memory films physically exposed to the source cavity, wherein sidewalls of the vertical semiconductor channels are physically exposed; and
forming the source contact layer in the source cavity directly on the sidewalls of the vertical semiconductor channels.

20. The method of claim 19, wherein:
the vertical semiconductor channels comprise a semiconductor material having a doping of a first conductivity type; and
the method further comprises:
selectively growing a doped semiconductor material having a doping of a second conductivity type from physically exposed surfaces of the vertical semiconductor channels, the lower source layer, and the upper source layer, and
isotropically recessing the doped semiconductor material underneath the backside trench, wherein a remaining portion of the doped semiconductor material constitutes the source contact layer.
